(19) United States
(12) Patent Application Publication
(10) Pub. No.: US 2025/0201660 A1
(43) Pub. Date: Jun. 19, 2025

(54) SEMICONDUCTOR PACKAGE

(71) Applicant: Samsung Electronics Co., Ltd., Suwon-si (KR)

(72) Inventors: Jinwoo Park, Suwon-si (KR); Unbyoung Kang, Suwon-si (KR)

(21) Appl. No.: 18/908,994

(22) Filed: Oct. 8, 2024

(30) Foreign Application Priority Data
Dec. 19, 2023 (KR) 10-2023-0185359

(51) Int. Cl. H01L 23/373; H01L 23/00; H01L 23/31; H01L 23/498; H01L 25/10

(52) U.S. Cl. CPC H01L 23/3736; H01L 23/49811; H01L 23/49822; H01L 24/24; H01L 25/105; H01L 23/3107; H01L 24/16; H01L 24/73; H01L 2224/16227; H01L 2224/24226; H01L 2224/73259; H01L 2225/1041; H01L 2225/1094

(57) ABSTRACT

A semiconductor package may include a lower redistribution layer structure including lower redistribution layers and a lower semiconductor chip, a sealing member on the lower semiconductor chip, through vias extending into the sealing member, an upper redistribution layer structure on the sealing member, a bonding pad and a heat slug pad on the upper redistribution layer structure, an upper package on the bonding pad, a plurality of heat slug posts on the heat slug pad, a thermal interface material layer on the heat slug pad and the plurality of heat slug posts, and a heat slug pattern on the thermal interface material layer, where the bonding pad is electrically connected to the upper redistribution layers, and where a thermal conductivity of the heat slug pad and a thermal conductivity of the plurality of heat slug posts is greater than a thermal conductivity of the thermal interface material layer.

### CROSS-REFERENCE TO RELATED APPLICATION

This application claims priority under 35 USC § 119 to Korean Patent Application No. 10-2023-0185359, filed on Dec. 19, 2023, in the Korean Intellectual Property Office (KIPO), the contents of which are incorporated by reference herein in their entirety.

### TECHNICAL FIELD

Various example embodiments relate to a semiconductor package. Particularly, various example embodiments relate to a semiconductor package including a fan out wafer level package (FOWPLP).

### BACKGROUND

In the semiconductor package having a package on package (POP) structure, a fan-out wafer level package may be disposed, and packages may be vertically stacked on an upper surface of the fan-out wafer level package. Heat generated from the fan-out wafer level package disposed at a lower portion of the semiconductor package may be transferred to an upper portion of the semiconductor package, and then the heat may need to be effectively dissipated to outside of the semiconductor package. However, it is not easy to improve the heat dissipation characteristics of the semiconductor package.

### SUMMARY

Various example embodiments provide a semiconductor package having enhanced heat dissipation characteristics.

According to some example embodiments, there is provided a semiconductor package. The semiconductor package may include a lower redistribution layer structure including lower redistribution layers, a lower semiconductor chip on the lower redistribution layer structure, the lower semiconductor chip electrically connected to the lower redistribution layers, a sealing member on the lower semiconductor chip on the lower redistribution layer structure, through vias extending into the sealing member, each of the through vias electrically connected to the lower redistribution layer structure, an upper redistribution layer structure on the sealing member, the upper redistribution layer structure including upper redistribution layers electrically connected to the through vias, a bonding pad and a heat slug pad on the upper redistribution layer structure, an upper package on the bonding pad, the upper package including at least one upper semiconductor chip, a plurality of heat slug posts on the heat slug pad, a thermal interface material layer on the heat slug pad and the plurality of heat slug posts, and a heat slug pattern on the thermal interface material layer, where the bonding pad is electrically connected to the upper redistribution layers, and where a thermal conductivity of the heat slug pad and a thermal conductivity of the plurality of heat slug posts is greater than a thermal conductivity of the thermal interface material layer.

According to some example embodiments, there is provided a semiconductor package. The semiconductor package may include a lower package including a lower redistribution layer structure, a lower semiconductor chip, and an upper redistribution layer structure, a bonding pad and a heat slug pad on the lower package, the bonding pad and the heat slug pad including a same metal, an upper package on the bonding pad, the upper package electrically connected to the bonding pad and including at least one upper semiconductor chip, a plurality of heat slug posts on the heat slug pad, a thermal interface material layer on the heat slug pad and the plurality of heat slug posts, and a heat slug pattern on the thermal interface material layer, where the heat slug pad faces the heat slug pattern in a first direction that is perpendicular to a lower surface of the lower package.

According to some example embodiments, there is provided a semiconductor package. The semiconductor package may include a lower redistribution layer structure including lower redistribution layers, a lower semiconductor chip on the lower redistribution layer structure, the lower semiconductor chip electrically connected to the lower redistribution layers, a sealing member on the lower semiconductor chip, through vias extending into the sealing member and electrically connected to the lower redistribution layers, the through vias at least partially surrounding the lower semiconductor chip, an upper redistribution layer structure on the sealing member, the upper redistribution layer structure including upper redistribution layers electrically connected to the through vias, a bonding pad and a heat slug pad on the upper redistribution layer structure, an upper package on the bonding pad and electrically connected to upper redistribution layers through the bonding pad, the upper package including at least one upper semiconductor chip, a plurality of heat slug posts on the heat slug pad, a thermal interface material layer on the heat slug pad and the heat slug posts, and a heat slug pattern on the thermal interface material layer, where the heat slug pattern is spaced apart from at least one sidewall of the upper package in a direction that is parallel to a lower surface of the lower redistribution layer structure.

According to example embodiments, the semiconductor package may include the heat slug structure including the heat slug pattern and the heat slug, the heat slug post, and the thermal interface material layer disposed under the heat slug pattern. The heat slug pad and the heat slug post having a thermal conductivity higher than a thermal conductivity of the thermal interface material layer may be disposed below the heat slug pattern, so that the heat slug pad and a heat slug post may serve as a heat dissipation passage. Therefore, heat generated in the semiconductor package may be effectively dissipated by the heat slug structure.

### BRIEF DESCRIPTION OF THE DRAWINGS

Various example embodiments will be more clearly understood from the following detailed description taken in conjunction with the accompanying drawings. FIGS. 1 to 27 represent various non-limiting, example embodiments as described herein.

FIG. 1 is a cross-sectional view illustrating a semiconductor package according to example embodiments;

FIGS. 2A and 2B are enlarged cross-sectional views illustrating an example of portion A of FIG. 1;

FIG. 3 is a plan view illustrating a semiconductor package according to example embodiments;

FIG. 4 is a plan view illustrating a semiconductor package according to some example embodiments;

FIG. 5 is a perspective view illustrating an example of a heat slug structure of a semiconductor package according to example embodiments;

FIG. 6 is a perspective view illustrating an example of a heat slug structure of a semiconductor package according to example embodiments;

FIG. 7 is a cross-sectional view illustrating a semiconductor package according to some example embodiments;

FIG. 8 is a cross-sectional view illustrating a semiconductor package according to some example embodiments;

FIG. 9 is a cross-sectional view illustrating a semiconductor package according to example embodiments;

FIGS. 10, 11, 12, 13, 14, 15, 16, 17, 18, and 19 are cross-sectional views illustrating a method of manufacturing a semiconductor package according to example embodiments;

FIG. 20 is a cross-sectional view illustrating a semiconductor package according to example embodiments;

FIG. 21 is an enlarged cross-sectional view illustrating an example of portion B of FIG. 20;

FIG. 22 is a cross-sectional view illustrating a semiconductor package according to some example embodiments;

FIG. 23 is a cross-sectional view illustrating a semiconductor package according to some example embodiments;

FIG. 24 is a cross-sectional view illustrating a semiconductor package according to some example embodiments; and

FIGS. 25, 26 and 27 are cross-sectional views illustrating a method of manufacturing a semiconductor package according to example embodiments.

### DETAILED DESCRIPTION

Hereinafter, various example embodiments will be described in detail with reference to the accompanying drawings.

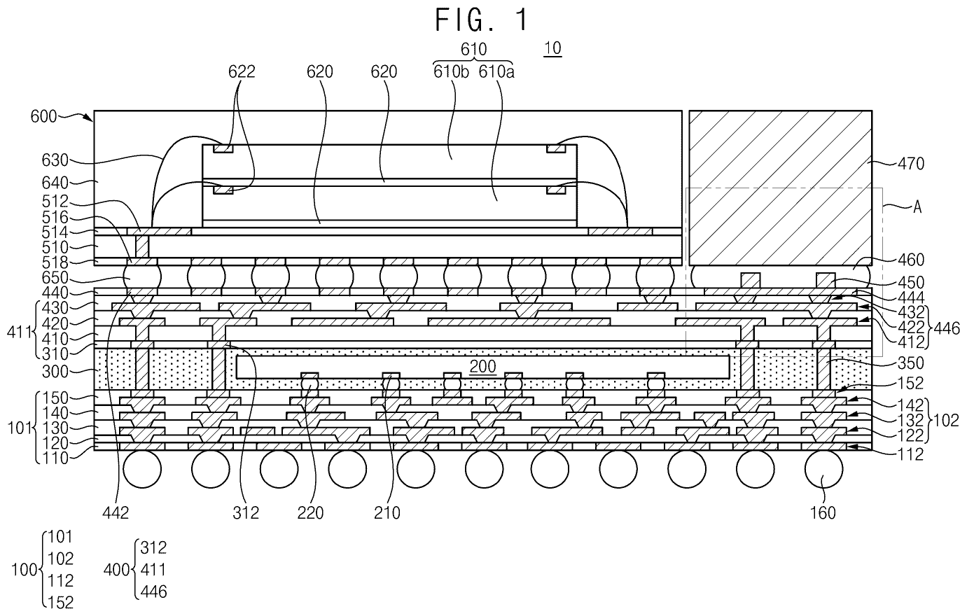

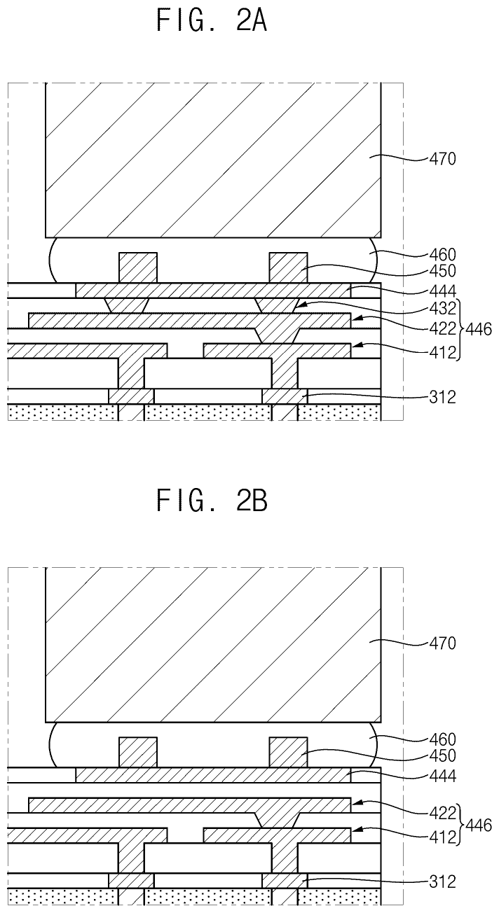

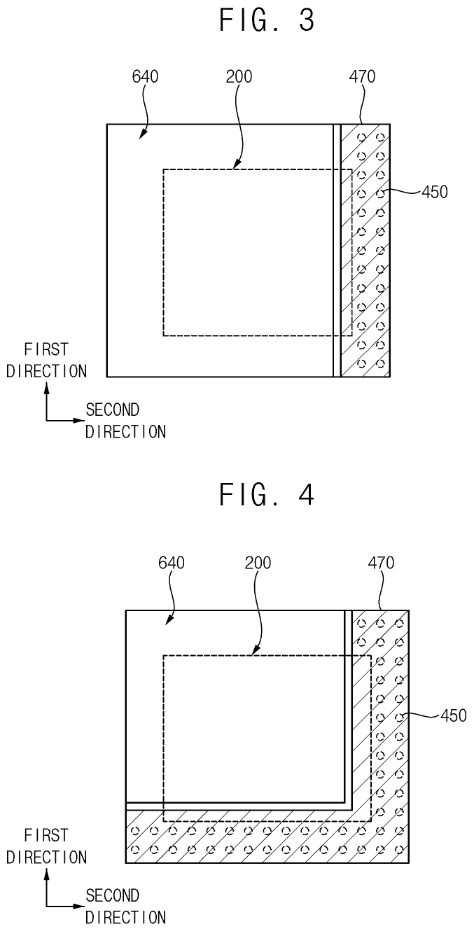

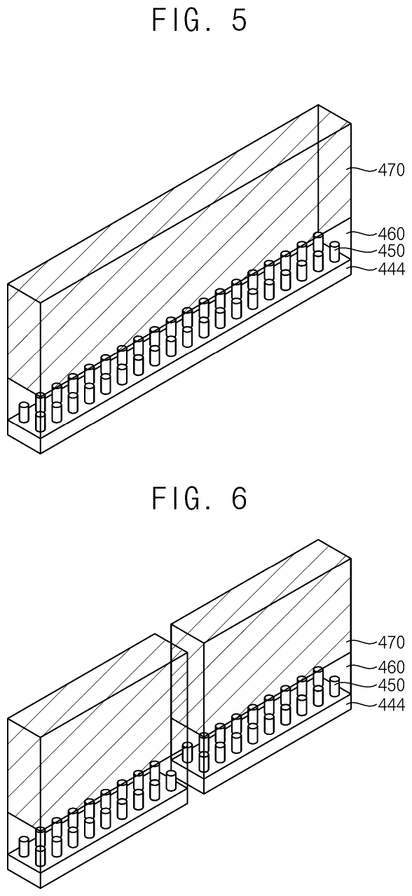

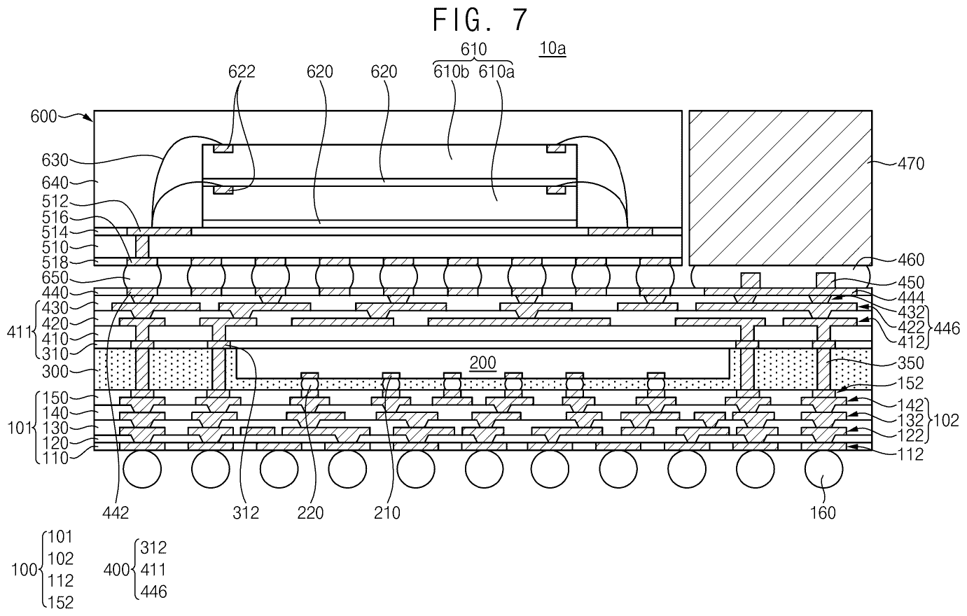

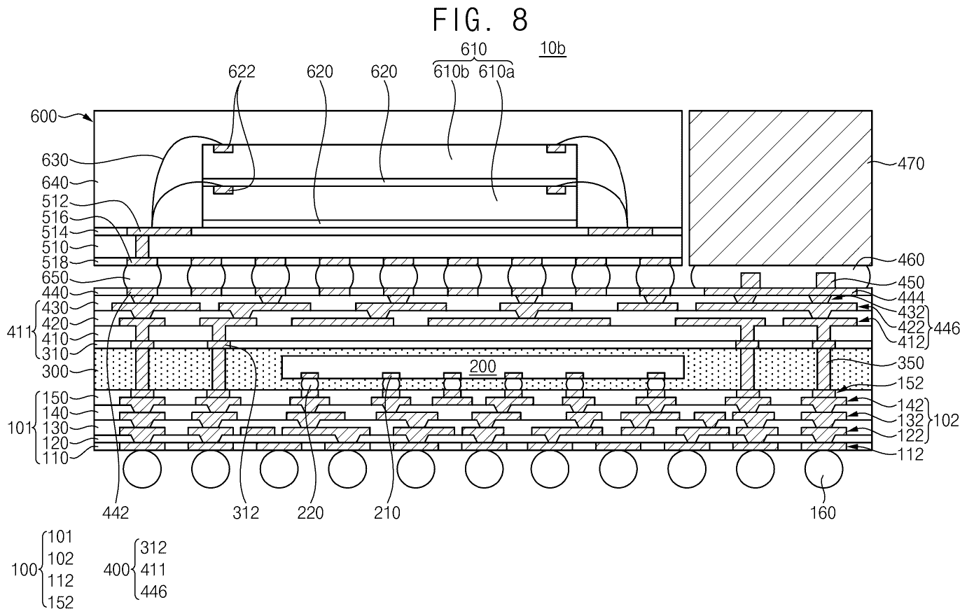

FIG. 1 is a cross-sectional view illustrating a semiconductor package according to example embodiments. FIGS. 2A and 2B are enlarged cross-sectional views illustrating an example of portion A of FIG. 1. FIG. 3 is a plan view illustrating a semiconductor package according to example embodiments. FIG. 4 is a plan view illustrating a semiconductor package according to some example embodiments. FIG. 5 is a perspective view illustrating an example of a heat slug structure of a semiconductor package according to example embodiments. FIG. 6 is a perspective view illustrating an example of a heat slug structure of a semiconductor package according to example embodiments. FIG. 7 is a cross-sectional view illustrating a semiconductor package according to some example embodiments. FIG. 8 is a cross-sectional view illustrating a semiconductor package according to some example embodiments.

Referring to FIGS. 1 to 6, a semiconductor package 10 may include a lower package, an upper package 600 disposed on the lower package, and a heat slug structure.

The lower package may include a lower redistribution layer (RDL) structure 100, a lower semiconductor chip 200 disposed on the lower redistribution layer structure 100, a first sealing member 300 covering or overlapping at least a portion of the lower semiconductor chip 200 on an upper surface of the lower redistribution layer structure 100, through vias 350 passing through or extending into the first sealing member 300, and an upper redistribution layer structure 400 disposed on the lower semiconductor chip 200 and the first sealing member 300.

In example embodiments, the lower package may be a fan-out package in which the lower redistribution layer structure 100 extends into the first sealing member 300 covering or overlapping an outer sidewall of the lower semiconductor chip 200.

The lower package may be provided as a system in package (SIP). For example, one or more lower semiconductor chips 200 may be disposed on the lower redistribution layer structure 100. The lower semiconductor chip 200 may include a logic chip including logic circuits. The logic chip may be a controller for controlling the memory chips. In example embodiments, the lower semiconductor chip 200 may be a processor chip such as an ASIC as a host such as a CPU, GPU, or SOC, or an application processor (AP).

The lower redistribution layer structure 100 may include lower insulation layers 101, lower redistribution layers 102, and first and second connection pads 112 and 152. The lower semiconductor chip 200 being electrically connected the lower redistribution layers 102 may be disposed on the lower redistribution layer structure 100. The lower redistribution layer structure 100 may serve as a front redistribution layer disposed opposite to a front surface of the lower semiconductor chip 200. Accordingly, the lower redistribution layer structure 100 may be a front redistribution layer (FRDL) of the fan-out package.

In example embodiments, the lower redistribution layer structure 100 may include first to fifth lower insulation layers 110, 120, 130, 140, and 150 and first to third lower redistribution layers 122, 132, and 142 formed in the second to fourth lower insulation layers 120, 130, and 140. Additionally, the first connection pad 112 may be disposed in the first lower insulation layer 110, which is a lowermost lower insulation layer. The second connection pad 152 may be disposed in the fifth lower insulation layer 150, which is an uppermost lower insulation layer.

The first to fifth lower insulation layers 110, 120, 130, 140, and 150 may include, e.g., a polymer, dielectric layer, etc. For example, the first to fifth lower insulation layers 110, 120, 130, 140, and 150 may include a photosensitive insulation layer such as a photo imageable dielectric (PID).

The first to third lower redistribution layers 122, 132, and 142 may include, e.g., copper (Cu), aluminum (Al), tin (Sn), nickel (Ni), gold (Au), silver (Ag), and platinum (Pt), or alloys thereof. In example embodiments, each of the first to third lower redistribution layers 122, 132, and 142 may include a via contact and a wiring line.

Each of the first and second connection pads 112 and 152 may serve as a bump pad. The bump pad may include a solder pad or pillar pad. For example, the first and second connection pads 112 and 152 may include copper (Cu), aluminum (Al), tin (Sn), nickel (Ni), gold (Au), silver (Ag), platinum (Pt), or alloys thereof. A bottom of the first connection pad 112 may not be covered or overlapped by the first lower insulation layer 110, and the bottom of the first connection pad 112 may be exposed.

The number and arrangement of the lower insulation layers 101 and the lower redistribution layers 102 included in the lower redistribution layer structure 100 may be presented as examples, and the present disclosure may not be limited thereto.

In example embodiments, the lower semiconductor chip 200 may include a plurality of chip pads 210, and the chip pads 210 may be on a first surface, i.e., an active surface of the lower semiconductor chip 200. The lower semiconductor chip 200 may be mounted on the lower redistribution layer structure 100 so that the first surface on which the chip pads 210 are formed may face the lower redistribution layer structure 100.

The lower semiconductor chip 200 may be mounted on the lower redistribution layer structure 100 with the conductive bumps 220 interposed therebetween. The conductive bump 220 may be disposed between the second connection pad 152 of the lower redistribution layer structure 100 and the chip pad 210 of the lower semiconductor chip 200, and thus the lower semiconductor chip 200 and the lower redistribution layers 102 may be electrically connected to each other by the conductive bump 220. For example, the conductive bump 220 may include a pillar bump on the chip pad 210 of the lower semiconductor chip 200 and a solder bump on the pillar bump.

Although only a few chip pads are shown in the drawings, structures and arrangements of the chip pads may be presented as examples, and the present disclosure may not be limited thereto. Additionally, only one lower semiconductor chip 200 on the lower redistribution layer structure 100 is shown, but the present disclosure may not be limited thereto. That is, a plurality of lower semiconductor chips may be stacked on the lower redistribution layer structure 100.

The first sealing member 300 may be on the upper surface of the lower redistribution layer structure 100, and may cover or overlap at least a portion of the lower semiconductor chip 200.

In example embodiments, as shown in FIG. 1, the first sealing member 300 may cover or overlap a lower portion, sidewalls, and an upper surface of the lower semiconductor chip 200. In this case, the upper surface of the lower semiconductor chip 200 may be covered or overlapped by the first sealing member 300. In some example embodiments, as shown in FIG. 7, in the semiconductor package 10a, the first sealing member 300 may cover or overlap the lower portion and the sidewalls of the lower semiconductor chip 200. In this case, the first sealing member 300 may expose the upper surface of the lower semiconductor chip 200.

For example, the first sealing member 300 may include, e.g., epoxy mold compound (EMC).

The plurality of through vias 350 may extend in a vertical direction to pass through or extend into the first sealing member 300. Each of the through vias 350 may be formed on the second connection pad 152. The upper surface of the through via 350 may be exposed by the first sealing member 300.

In example embodiments, the through vias 350 may be arranged to at least partially surround the lower semiconductor chip 200. The through vias 350 may be disposed in an area surrounding the lower semiconductor chip 200. Each of the through vias 350 may pass through or extend into the first sealing member 300, and may serve as an electrical connection path between the upper semiconductor chip 610 and the lower semiconductor chip 200. The through via 350 may be a through mold via (TMV) formed through the first sealing member 300. The through vias 350 may be disposed in a fan-out region of outside an area for forming the lower semiconductor chip 200, and the lower redistribution layer 102 and the upper redistribution layer 446 may be electrically connected to each other by the through vias 350.

The through via 350 may include metal. The through via 350 may include, e.g., copper.

The upper redistribution layer structure 400 may be disposed on upper surfaces of the lower semiconductor chip 200 and the first sealing member 300. The upper redistribution layer structure 400 may include upper insulation layers 411 and upper redistribution layers 446.

The upper redistribution layer structure 400 may be on the first sealing member 300, and may serve as a backside redistribution layer. Accordingly, the upper redistribution layer structure 400 may be the backside redistribution layer (BRDL) of the fan-out package. The upper redistribution layer structure 400 may be electrically connected to the lower redistribution layer structure 100 through the through via 350.

In example embodiments, the upper redistribution layer structure 400 may include first to fourth upper insulation layers 310, 410, 420, and 430 and first to third upper redistribution layer 412, 422 and 432 in the second and third upper insulation layers 410 and 420. The pad pattern 312 may be disposed in the first upper insulation layer 310, which is a lowermost upper insulation layer. The pad pattern 312 may contact an upper surface of the through via 350. The first and second upper redistribution layers 412 and 422 may include via contacts and wiring lines. The third upper redistribution layer 432 in the fourth upper insulation layer 430, which is an uppermost upper insulation layer of the upper redistribution layer structure 400, may include an uppermost via contact.

First bonding pads 442 and a heat slug pad 444 may be disposed on the fourth upper insulation layer 430, which is the uppermost upper insulation layer of the upper redistribution layer structure 400.

The first bonding pads 442 may face the upper package 600 in the vertical direction. Each of the first bonding pads 442 may contact the third upper redistribution 432. A fifth upper insulation layer 440 may be disposed between the first bonding pads 442 and between the first bonding pad and the heat slug pad 444 on the upper redistribution layer structure 400. The fifth upper insulation layer 440 may not cover or overlap upper surfaces of the heat slug pad 444 and the first bonding pads 442.

The first bonding pads 442 may be provided as pads for electrically connecting the lower package and the upper package 600. Accordingly, the first bonding pads 442 may be disposed to face a lower surface of the upper package 600. A bottom of each of the first bonding pads 442 may contact the third upper redistribution layer 432. The first bonding pads 442 may be electrically connected to the upper redistribution layer 446.

The heat slug pad 444 may be disposed on the upper wiring structure, and may be disposed to face a heat slug pattern 470 in the vertical direction.

In example embodiments, as shown in FIG. 2A, at least a portion of a bottom of the heat slug pad 444 may contact upper surfaces of via contacts serving as the third upper redistribution layer 432. Additionally, the heat slug pad 444 may be electrically connected to the upper redistribution layer structure 400, the through via 350, the lower redistribution layers 102, and the first and second connection pads 112 and 152. In this case, the heat slug pad 444 may be electrically connected to a ground (Vss) line (or ground level) through the upper redistribution layer structure 400, the through via 350, the lower redistribution layers 102, and the first and second connection pads 112 and 152. However, the heat slug pad 444 may not be connected to other signal lines, except for the ground line.

In some example embodiments, as shown in FIG. 2B, the heat slug pad 444 may be spaced apart from the upper redistribution layers in a vertical direction (e.g., a direction that is perpendicular to a lower surface of the lower redistribution layer structure 100). A bottom of the heat slug pad 444 may not contact an upper surface of the third upper redistribution layer 432. That is, the bottom of the heat slug pad 444 may not contact an uppermost via contact in the upper redistribution layers. In this case, the heat slug pad 444 may be electrically floating, without being electrically connected lower wirings.

In some example embodiments, at least a portion of a bottom of the heat slug pad 444 may be connected to at least a portion of the upper redistribution layers 446 but may not be connected to the through via 350. In this case, the heat slug pad 444 may be floating, without being electrically connected the lower redistribution layers 102.

The first bonding pad 442 and the heat slug pad 444 may include the same metal. In example embodiments, the first bonding pad 442 and the heat slug pad 444 may include copper (Cu), aluminum (Al), tin (Sn), nickel (Ni), gold (Au), silver (Ag), platinum (Pt), or alloys thereof. For example, the first bonding pad 442 and the heat slug pad 444 may include copper, and an upper surface of the copper may be covered with gold, silver, or nickel by a surface treatment.

Heat slug posts (or heat slug pillars) 450 may be disposed on the heat slug pad 444. The heat slug posts 450 may protrude or extend from an upper surface of the heat slug pad 444.

Each of the heat slug posts 450 may include a metal having a thermal conductivity higher than a thermal conductivity of a thermal interface material layer 460, which is described below in further detail. The heat slug post 450 may include, e.g., copper (Cu), aluminum (Al), tin (Sn), nickel (Ni), gold (Au), silver (Ag), platinum (Pt), or alloys thereof. For example, the heat slug post 450 may include copper, and the upper surface of the copper may be covered with gold, silver, or nickel.

The heat slug posts 450 may be spaced apart from each other. In example embodiments, the heat slug posts 450 may be arranged regularly and repeatedly. In some example embodiments, the heat slug posts 450 may be disposed on hot spots where heat dissipation is desired.

For example, the heat slug post 450 may have a thermal conductivity of about 350W/m.k to about 420 W/m.k. When the heat slug post 450 includes copper, the heat slug post 450 may have a thermal conductivity of about 400 W/m.k.

The thermal interface material layer 460 may be on the heat slug pad 444 and the heat slug posts 450, and the thermal interface material layer 460 may cover or at least partially overlap the heat slug pad 444 and the heat slug posts 450. The heat slug pattern 470 may be disposed on the thermal interface material layer 460. The heat slug pad 444, the heat slug posts 450, the thermal interface material layer 460 and the heat slug pattern 470 may serve as a heat slug structure. The thermal interface material layer 460 may contact an entire upper surface of the heat slug pad 444 and at least a portion of the heat slug post 450. The thermal interface material layer 460 may contact a sidewall of the heat slug post 450.

In example embodiments, the thermal interface material layer 460 may contact an upper surface of the heat slug post 450. The thermal interface material layer 460 may be interposed between the upper surface of the heat slug post 450 and the heat slug pattern 470. Accordingly, the heat slug post 450 may be spaced apart from the heat slug pattern 470 in the vertical direction.

In some example embodiments, the thermal interface material layer 460 may not be disposed between the upper surface of the heat slug post 450 and the heat slug pattern 470. Accordingly, the heat slug post 450 may contact the heat slug pattern 470.

The thermal interface material layer 460 may include, e.g., grease or a thermosetting resin layer. The thermal interface material layer 460 may further include filler particles dispersed in the thermosetting resin layer. The filler particles may include metal powder or graphene powder having high thermal conductivity. Alternatively, the filler particles may include, e.g., at least one of silica, alumina, zinc oxide, and nitrogen boride.

For example, the thermal interface material layer 460 may have a thermal conductivity of about 2 W/m.k to about 6 W/m.k.

The heat slug pattern 470 may include metal. In example embodiments, the heat slug pattern 470 may include copper (Cu), aluminum (Al), tin (Sn), nickel (Ni), gold (Au), platinum (Pt), or an alloy thereof. For example, the heat slug pattern 470 may include copper, and an upper surface of the copper may be covered with gold, silver, or nickel by a surface treatment.

The heat slug pattern 470 may be provided to dissipate to outside heat generated when the lower semiconductor chip 200 included in the lower package is driven. The heat slug pad 444 and the heat slug posts 450 including the metal having high thermal conductivity (e.g., copper) may be disposed to face the heat slug pattern 470. As the heat slug pad 444 and the heat slug posts 450 are included in the semiconductor package, the heat generated when the lower semiconductor chip 200 included in the lower package is driven may be easily guided to the heat slug pattern 470. The heat may be dissipated to the outside through the heat slug pattern 470. Accordingly, deterioration of the semiconductor chips due to the heat generation from the semiconductor chips included in the semiconductor package may be decreased or inhibited.

In example embodiments, as shown in FIG. 1, a portion of the heat slug pattern 470 may overlap the lower semiconductor chip 200 included in the lower package in the vertical direction. In this case, the heat generated from the lower semiconductor chip 200 may be effectively dissipated to the heat slug pattern 470.

However, a position of the heat slug pattern 470 may not be limited to thereto. The heat slug pattern 470 may be disposed on a remaining space after placing the lower semiconductor chip 200 and the upper semiconductor chip 610. In some example embodiments, as shown in FIG. 8, the heat slug pattern 470 may not overlap the lower semiconductor chip 200 in the vertical direction, according to sizes and arrangements of the lower semiconductor chip 200 and the upper semiconductor chip 610.

One sidewall (e.g., an outer sidewall) of the heat slug pattern 470 may be aligned with an edge of the lower package, and the heat slug pattern 470 may extend in at least one direction.

The heat slug pad 444 may be under the heat slug pattern 470, and may be disposed within an area vertically facing the heat slug pattern 470. As shown in FIG. 5, one heat slug pad 444 may be disposed within the area vertically facing the heat slug pattern 470. That is, the heat slug pad 444 may have single pattern shape. As shown in FIG. 6, a plurality of heat slug pads 444 may be disposed within the area vertically facing the heat slug pattern 470, and the plurality of heat slug pads 444 may be spaced apart from each other.

In example embodiments, as shown in FIG. 3, the heat slug pattern 470 may extend in a first direction along one edge of the lower package. In this case, the heat slug pad 444 may have, e.g., a single pattern shape without a cutting portion in a second direction perpendicular to the first direction. Alternatively, a plurality of heat slug pads 444 may be spaced apart from each other in the first direction and/or the second direction.

In some example embodiments, as shown in FIG. 4, the heat slug pattern 470 may extend in the first direction and the second direction, respectively, along two edges of the lower package. Accordingly, the heat slug pattern 470 may have an L-shape. In this case, for example, the heat slug pad 444 may have a shape of one pattern disposed within an L-shaped area facing the lower surface of the heat slug pattern 470. Alternatively, a plurality of heat slug pads 444 may be disposed in the L-shaped area facing the lower surface of the heat slug pattern 470.

In some example embodiments, the heat slug pattern 470 may extend in the first direction and the second direction, respectively, along four edges of the lower package. Accordingly, the heat slug pattern 470 may have a square ring shape at least partially surrounding edges of the lower package. In this case, for example, the heat slug pad 444 may have a shape of one pattern disposed in an area facing the lower surface of the heat slug pattern 470 and having the square ring shape. Alternatively, a plurality of heat slug pads 444 may be disposed in an area facing the lower surface of the heat slug pattern 470 and having the square ring shape.

The upper package 600 may be stacked on the lower package. The heat slug pattern 470 may be laterally spaced apart from at least one sidewall of the upper package 600.

In example embodiments, the upper package 600 may include a package substrate 510, a plurality of upper semiconductor chips 610 mounted on the package substrate 510, and a second sealing member 640 covering or overlapping the upper semiconductor chips 610 on the upper semiconductor chips 610 and the package substrate 510. Bonding wirings 630 for connecting the upper semiconductor chips 610 to each other may be further included in the upper package 600.

In the upper package 600, a plurality of upper semiconductor chips 610a and 610b may be sequentially stacked on the package substrate 510 using adhesive members. The bonding wirings 630 may connect upper chip pads 622 of the upper semiconductor chips 610 and third connection pads 512 of the package substrate 510. Insulation layers 514 may be disposed on both sides of the third connection pads 512.

Second bonding pads 516 may be on the lower surface of the package substrate 510, and insulation layers 518 may be disposed on both sides of the second bonding pads 516. The second bonding pads 516 may be electrically connected to the third connection pad 512.

As described above, the upper package 600 may include two semiconductor chips mounted by a wire bonding process. However, the number and mounting method of the semiconductor chips included in the upper package 600 may not be limited thereto.

Conductive connection members 650 may be on the first bonding pads 442 of the lower package, respectively, and the upper package 600 may be bonded on the conductive connection members 650. Each of the conductive connection members 650 may include, e.g., a solder ball, conductive bump, etc. Each of the conductive connection members 650 may be interposed between the first bonding pad 442 on the upper redistribution layer structure 400 and the second bonding pad 516 of the package substrate 510. Accordingly, the lower package and the upper package 600 may be electrically connected to each other by the conductive connection members 650.

As described above, the heat slug pad 444 including the metal having high thermal conductivity may be formed under the heat slug pattern 470 to face the heat slug pattern 470. Additionally, a plurality of heat slug posts 450 including the metal having high thermal conductivity may be formed on the heat slug pad 444. Therefore, the heat generated from semiconductor chips included in the semiconductor package may be quickly transferred to the heat slug pattern 470 through the heat slug pad 444 and the heat slug post 450, and the heat generated from semiconductor chips included in the semiconductor package may be effectively dissipated through the heat slug pattern 470. Therefore, the semiconductor package may have excellent operating characteristics.

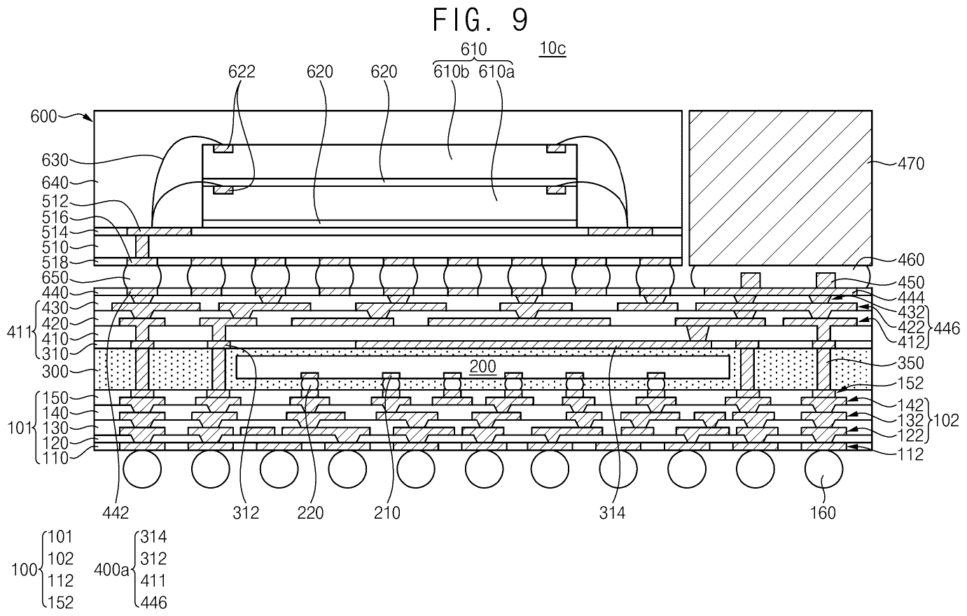

FIG. 9 is a cross-sectional view illustrating a semiconductor package according to example embodiments.

The semiconductor package shown in FIG. 9 may be the same or similar to the semiconductor package shown in FIG. 1, except for a portion of an upper redistribution layer structure. Therefore, repeated descriptions may be omitted.

Referring to FIG. 9, an upper redistribution layer structure 400a may be disposed on an upper surface of the lower semiconductor chip 200 and the first sealing member 300. The upper redistribution layer structure 400a may include upper insulation layers 411 and upper redistribution layers 446. The first bonding pad 442 and the heat slug pad 444 may be disposed on an upper surface of the upper redistribution layer structure 400a. The heat slug posts 450 may be disposed on the heat slug pad 444.

The upper redistribution layer structure 400a may include the first to fourth upper insulation layers 310, 410, 420, and 430 and the first to third upper redistributions 412, 422, and 432 in the first to third upper insulation layers 410, 420, and 430. The pad pattern 312 and the lower heat slug pattern 314 may be disposed within the first upper insulation layer 310, which is a lowermost upper insulation layer.

The lower heat slug pattern 314 may include a metal having high thermal conductivity. In example embodiments, the lower heat slug pattern 314 may include copper (Cu), aluminum (Al), tin (Sn), nickel (Ni), gold (Au), silver (Ag), platinum (Pt), or an alloy thereof. The lower heat slug pattern 314 may the same material as the pad pattern 312.

At least a portion of the lower heat slug pattern 314 may overlap the lower semiconductor chip 200 in the vertical direction (e.g., a direction that is perpendicular to a lower surface of the lower redistribution layer structure 100).

The first sealing member 300 may cover or at least partially surround a lower portion, a sidewall, and an upper portion of the lower semiconductor chip 200. Accordingly, the first sealing member 300 may be disposed between the lower heat slug pattern 314 and the lower semiconductor chip 200. The lower heat slug pattern 314 and the lower semiconductor chip 200 may be insulated from each other.

The lower heat slug pattern 314 may be connected to the upper redistribution layers 446, the heat slug pad 444, and the heat slug posts 450 disposed thereon. However, the lower heat slug pattern 314 may not be electrically connected to the first bonding pad 442.

In example embodiments, the lower heat slug pattern 314 may be electrically connected to the through via 350, the lower redistribution layers 102, and the first and second connection pads 112 and 152 through the upper redistribution layers 446. In this case, the lower heat slug pattern 314 may be connected to a ground line through the second connection pad 152, and may not be connected to other signal lines except for the ground line.

Since at least a portion of the lower heat slug pattern 314 overlaps the lower semiconductor chip 200, heat generated from the lower semiconductor chip 200 may be quickly transferred to the lower heat slug pattern 314. Accordingly, the heat generated from the lower semiconductor chip 200 may be transferred to the heat slug pattern 470 through the upper redistribution layers 446, the heat slug pad 444, and the heat slug posts 450. The heat generated from the lower semiconductor chip 200 may be dissipated outside of the semiconductor package 10c.

Hereinafter, a method of manufacturing the semiconductor package of FIG. 1 may be described.

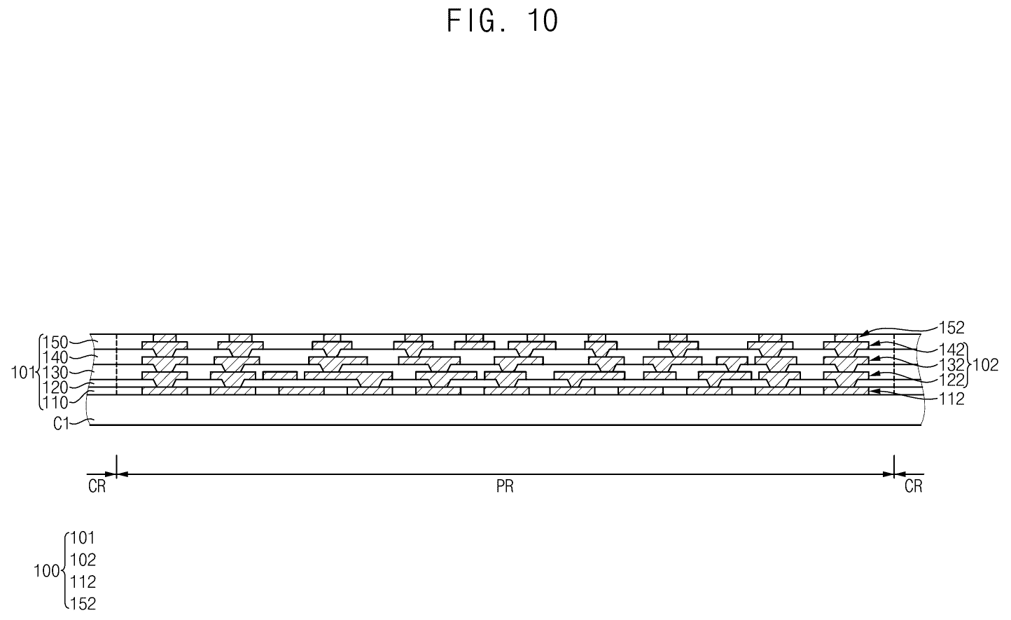

FIGS. 10 to 19 are cross-sectional views illustrating a method of manufacturing a semiconductor package according to example embodiments.

Referring to FIG. 10, a lower redistribution layer structure 100 may be formed on a first carrier substrate C1. The lower redistribution layer structure 100 may include lower insulation layers 101, lower redistribution layers 102, and first and second connection pads 112 and 152.

The first carrier substrate C1 may be a base substrate for placing a plurality of semiconductor chips on the lower redistribution layer structure 100 and forming a sealing member covering the plurality of semiconductor chips. In example embodiments, the first carrier substrate C1 may have a shape corresponding to a shape of a wafer on which a semiconductor process is performed. In example embodiments, the first carrier substrate C1 may include a silicon substrate, a glass substrate, a non-metallic plate, or a metal plate.

The first carrier substrate C1 may include a package region PR on which the semiconductor chip is mounted and a cut region CR surrounding the package region PR. As will be described later, the first carrier substrate C1 may cut along the cut region CR so that the lower redistribution layer structure 100 and the sealing member may be individualized.

First, first connection pads 112 and first lower insulation layer 110 may be formed on the first carrier substrate C1. In example embodiments, the first connection pads 112 may be formed by a plating process. Particularly, a release film, a barrier metal layer, a seed layer, and the first lower insulation layer 110 may be sequentially formed on the first carrier substrate C1, and then the first lower insulation layer 110 may be etched to form openings exposing the seed layer on first connection pad regions. Thereafter, the plating process may be performed on the seed layer to form the first connection pads 112 in the openings.

Subsequently, a second lower insulation layer 120 covering or overlapping the first connection pads 112 may be formed on the first lower insulation layer 110, and then the second lower insulation layer 120 may be patterned to form first openings exposing at least portions of the first connection pads 112. A first lower redistribution layer 122 may be formed on the second lower insulation layer 120 to at least partially fill the first openings. The first lower redistribution layer 122 may pass through or extend into the second lower insulation layer 120, and may be electrically connected to the first connection pads 112.

Similarly, a third lower insulation layer 130 covering or overlapping the first lower redistribution layers 122 may be formed on the second lower insulation layer 120, and then the third lower insulation layer 130 may be patterned to form second openings exposing at least portions of the first lower redistribution layers 122. The second lower redistribution layers 132 may be formed on the third lower insulation layer 130 to at least partially fill the second openings. The second lower redistribution layer 132 may pass through or extend into the third lower insulation layer 130, and may be electrically connected to the first lower redistribution layer 122.

A fourth lower insulation layer 140 covering or overlapping the second lower redistribution layers 132 may be formed on the third lower insulation layer 130, and then the fourth lower insulation layer 140 may be patterned to form third openings exposing at least portions of the second lower redistribution layers 132. The third lower redistribution layers 142 may be formed on the fourth lower insulation layer 140 to at least partially fill the third openings. The third lower redistribution layer 142 may pass through or extend into the fourth lower insulation layer 140, and may be electrically connected to the second lower redistribution 132.

Subsequently, second connection pads 152 may be formed on the third lower redistribution layers 142. Thereafter, a fifth lower insulation layer 150 may be formed on the fourth lower insulation layer 140 to cover or overlap the third lower redistribution layers 142 and expose an upper surface of the second connection pad 152.

The first to fifth lower insulation layers 110, 120, 130, 140, and 150 may include, e.g., a polymer or a dielectric material. The first to fifth lower insulation layers 110, 120, 130, 140, and 150 may include, e.g., a photosensitive insulating material (PID). The first to fifth lower insulation layers 110, 120, 130, 140, and 150 may be formed by a spin coating process, a vapor deposition process, or the like.

The first and second connection pads 112 and 152 may be, e.g., bump pads. The bump pad may include, e.g., a solder pad or pillar pad. For example, the first and second connection pads 112 and 152 may include copper (Cu), aluminum (Al), tin (Sn), nickel (Ni), gold (Au), silver (Ag), platinum (Pt), or alloys thereof.

Accordingly, a lower redistribution layer structure 100 including the first to fifth lower insulation layers 110, 120, 130, 140, 150, the first connection pad 112, the second connection pad 152 and first to third lower redistribution layers 122, 132, and 142 may be formed on the first carrier substrate C1. The first to third lower redistribution layers included in the lower redistribution layer structure 100 are collectively referred to as a lower redistribution layer 102.

The lower redistribution layer structure 100 may serve as a front redistribution layer (FRDL) of a fan-out package. The second connection pads 152 may be exposed by an upper surface of the lower redistribution layer structure 100.

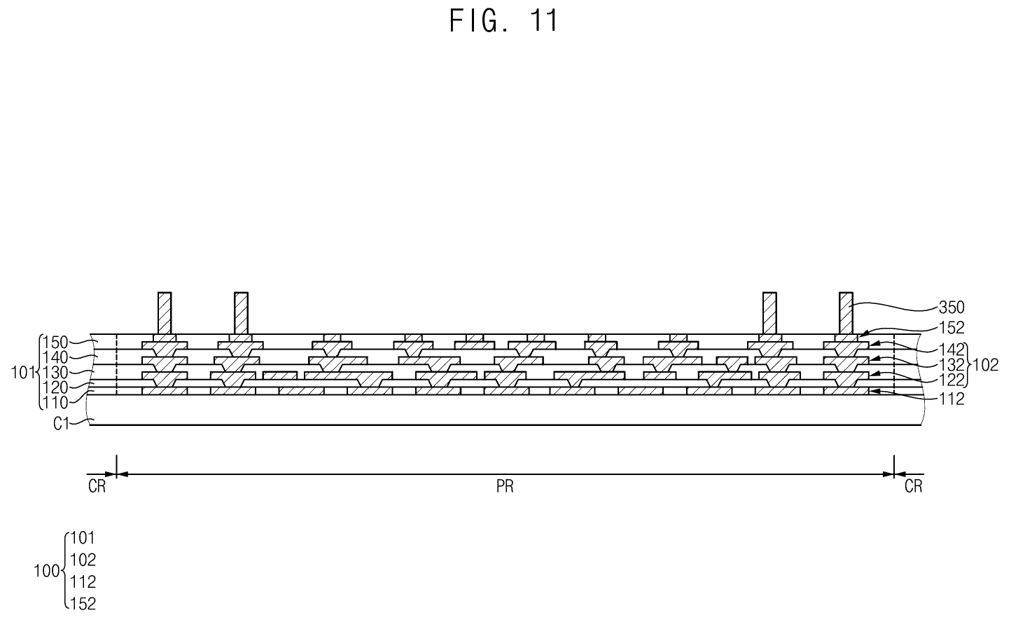

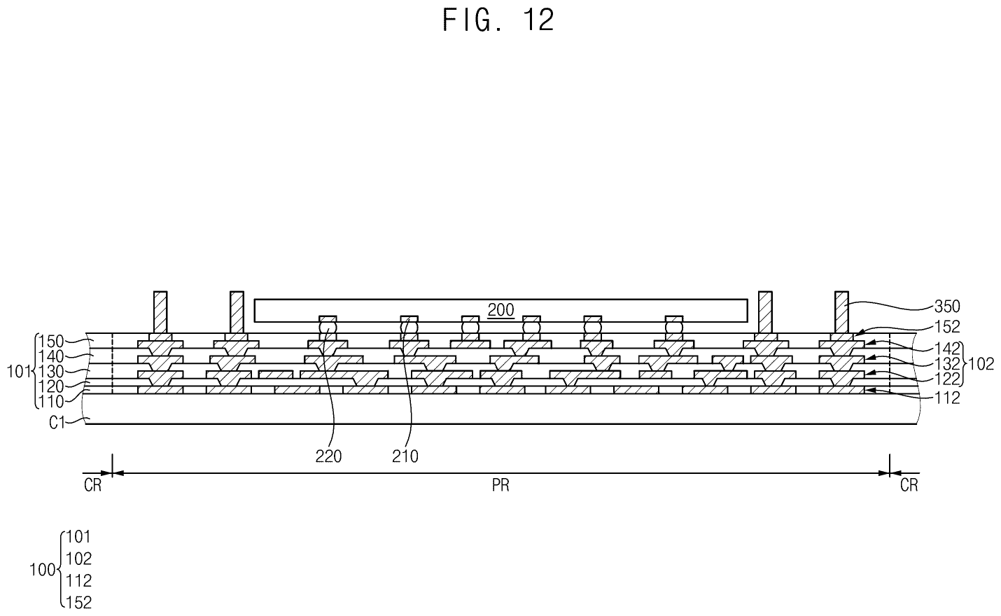

Referring to FIG. 11, a plurality of through vias 350 serving as conductive structures may be formed on the upper surface of the lower redistribution layer structure 100.

In example embodiments, a photoresist layer may be formed on the upper surface of the lower redistribution layer structure 100, and an exposure process may be performed on the photoresist layer to form a photoresist pattern having openings for forming a plurality of through vias on a fan-out region of the lower redistribution layer structure 100. The openings may expose at least a portion of the second connection pad 152 in the fan-out region.

Subsequently, a conductive material may fill the openings of the photoresist pattern to form a through vias 350. The photoresist pattern may be removed by a strip process. In example embodiments, the through via 350 may include a metal formed by an electro-plating process. The through via 350 may include, e.g., copper.

The through vias 350 may extend from an upper surface of the second connection pad 152 in the vertical direction (e.g., a direction that is perpendicular to a lower surface of the lower redistribution layer structure 100). The through vias 350 may be electrically connected to lower redistribution layers 102 included in the lower redistribution layer structure 100. The through vias 350 may be positioned on a fan-out region outside a fan-in region where the semiconductor chip (die) is positioned.

Referring to FIG. 12, at least one lower semiconductor chip 200 may be mounted on the fan-in region of the lower redistribution layer structure 100.

The lower semiconductor chip 200 may be disposed so that a front surface (i.e., active surface) on which the chip pads 210 are formed may face the lower redistribution layer structure 100. The chip pads 210 of the lower semiconductor chip 200 may be electrically connected to the second connection pads 152 of the lower redistribution layer structure 100 through conductive bumps 220. Accordingly, the lower semiconductor chip 200 may be electrically connected to the lower redistribution layers 102 of the lower redistribution layer structure 100 through conductive bumps 220. For example, the conductive bump 220 may include, e.g., a micro bump (uBump).

The lower semiconductor chip 200 may be a logic chip including logic circuits. The logic chip may be a controller for controlling memory chips. In example embodiments, the lower semiconductor chip 200 may be a processor chip such as an ASIC as a host such as a CPU, GPU, or SOC, or an application processor (AP).

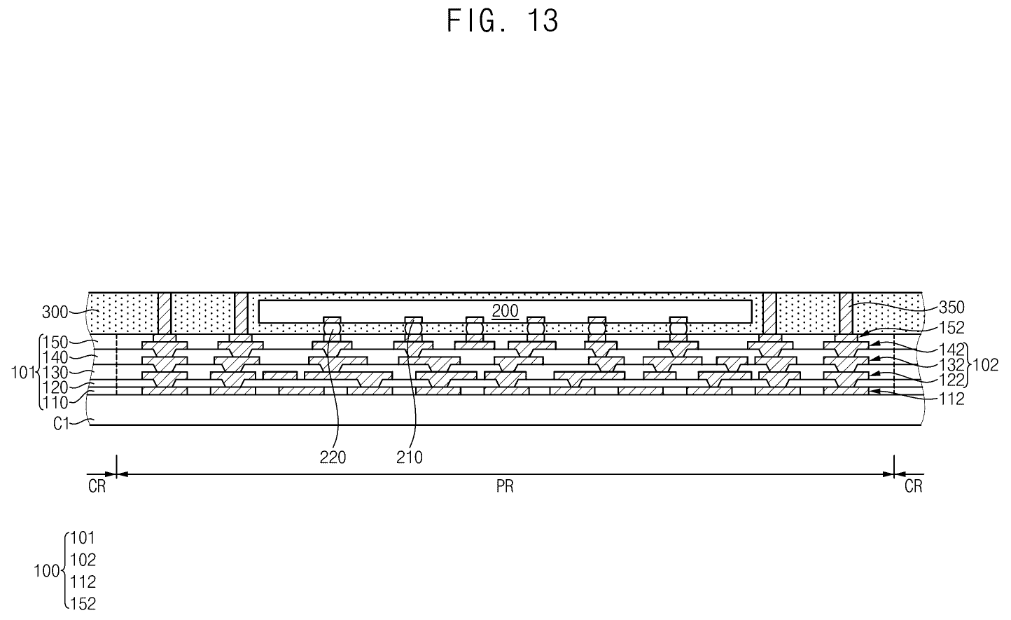

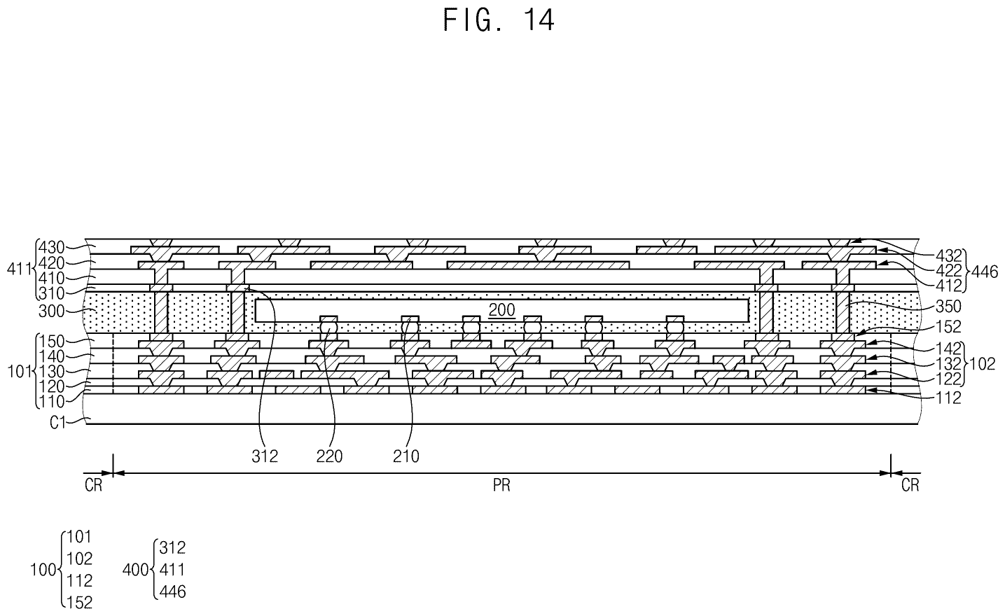

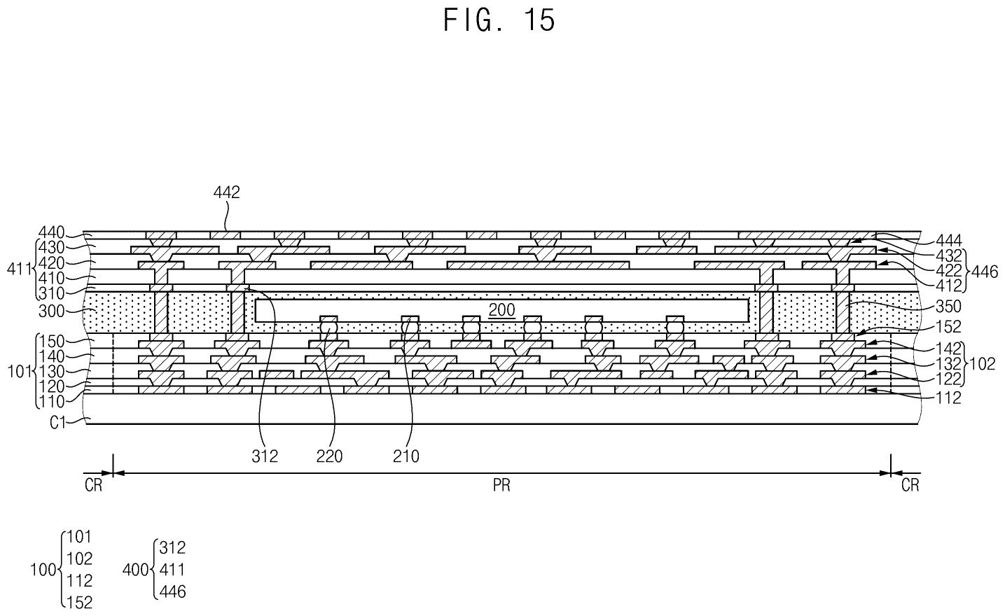

Referring to FIG. 13, a sealing material may be formed on the lower redistribution layer structure 100 to cover or overlap the lower semiconductor chip 200 and the plurality of through vias 350.

The sealing material may be formed to at least partially fill a space between the lower redistribution layer structure 100 and the lower semiconductor chip 200, and the sealing material may be formed to cover or overlap the upper surface of the lower semiconductor chip 200 and the upper surfaces of the plurality of through vias 350. For example, the sealing material may include an epoxy mold compound (EMC). The sealing material 230 may include UV resin, polyurethane resin, silicone resin, silica filler, etc.

The sealing material may be formed by a molding process, a screen printing process, a lamination process, etc.

An upper portion of the sealing material may be removed to form a first sealing member 300 exposing upper surfaces of the plurality of through vias 350. In example embodiments, the upper portion of the sealing material may be removed by a grinding process.

In example embodiments, the first sealing member 300 may cover or overlap a bottom, sidewalls, and an upper surface of the lower semiconductor chip 200.

In some example embodiments, the first sealing member 300 may cover or overlap the lower portion and sidewalls of the lower semiconductor chip 200. In this case, as shown in FIG. 7, the upper surface of the lower semiconductor chip 200 may be exposed by the first sealing member 300.

Accordingly, a plurality of through vias 350 may be formed on the fan-out region of the lower redistribution layer structure 100, and the plurality of through vias 350 may extend through the first sealing member 300. The through via 350 may be a through mold via (TMV) passing through or extending into the first sealing member 300.

Referring to FIG. 14, an upper redistribution layer structure 400 may be formed on the upper surface of the first sealing member 300. The upper redistribution layer structure 400 may include a pad pattern 312, an upper insulation layer 411, and an upper redistribution layer 446.

In example embodiments, a first upper insulation layer 310 may be formed on the upper surface of the first sealing member 300, and then the first upper insulation layer 310 may be patterned to form fourth openings exposing one ends of the through vias 350. The fourth openings may expose upper surfaces of the through vias 350. For example, the first upper insulation layer 310 may include silicon oxide, silicon nitride, silicon oxynitride, etc.

Subsequently, a seed layer may be formed on portions of the through vias 350 and in the fourth openings, and then the seed layer may be patterned. An electro-plating process may be performed to form the pad patterns 312 including a metal. The pad patterns 312 may include, e.g., copper.

A second upper insulation layer 410 may be formed on the first upper insulation layer 310 and the pad patterns 312, and then the second upper insulation layer 410 may be patterned to form fifth openings exposing at least portions of the pad patterns 312. First upper redistribution layer 412 may be formed on the second upper insulation layer 410 to at least partially fill the fifth openings. The first upper redistribution layer 412 may pass through or extend into the second upper insulation layer 410, and may be electrically connected to the pad patterns 312.

Similarly, a third upper insulation layer 420 covering or overlapping the first upper redistributions 412 may be formed on the second upper insulation layer 410, and then the third upper insulation layer 420 may be patterned to form sixth openings exposing at least portions of the first upper redistribution layers 412. A second upper redistribution layer 422 may be formed on the third upper insulation layer 420 to at least partially fill the sixth openings. The second upper redistribution layer 422 may pass through or extend into the third upper insulation layer 420, and may be electrically connected to the first upper redistribution 412.

A fourth upper insulation layer 430 covering or overlapping the second upper redistributions 422 may be formed on the third upper insulation layer 420, and then the fourth upper insulation layer 430 may be patterned to form seventh openings exposing at least portions of the second upper redistribution layer 422. A third upper redistribution layer 432 may be formed to at least partially fill the seventh opening of the fourth upper insulation layer 430. The third upper redistribution layer 432 may be an uppermost via contact.

Referring to FIG. 15, first bonding pads 442 and heat slug pad 444 may be formed on the upper redistribution layer structure 400.

The first bonding pads 442 may be disposed at a region corresponding to a region for forming an upper semiconductor chip. The heat slug pad 444 may be disposed at a region corresponding to a region for forming a heat slug member.

The first bonding pad 442 may contact an upper surface of the third upper redistribution layer 432, which is an uppermost upper redistribution layer.

In example embodiments, at least portions of a bottom of the heat slug pad 444 may contact the upper surface of the third upper redistribution layer 432. In some example embodiments, the bottom of the heat slug pad 444 may not contact the third upper redistribution layer 432.

Since the first bonding pads 442 and the heat slug pad 444 are formed by the same process, the first bonding pads 442 and the heat slug pad 444 may include the same metal.

In example embodiments, a photoresist layer may be formed on the upper redistribution layer structure 400, and an exposure process may be performed on the photoresist layer to form a photoresist pattern. The photoresist pattern may include eighth openings exposing the upper surface of the third upper redistribution layer 432 in the region for forming the upper semiconductor chip, and ninth openings exposing a region for forming the heat slug pads 444

Subsequently, a metal may at least partially fill the eighth and ninth openings of the photoresist pattern to form first bonding pads 442 in the eighth openings and heat slug pads 444 in the ninth opening, respectively. In example embodiments, the first bonding pads 442 and the heat slug pads 444 may be formed by electro-plating process. The first bonding pads 442 and the heat slug pads 444 may include, e.g., copper. After performing the electro-plating process, a metal surface treatment process may be further performed. For example, the first bonding pads 442 and the heat slug pads 444 may include copper, and the upper surface of the copper may be covered with gold, silver, or nickel.

In the plan view, the heat slug pad 444 may have a shape similar to a shape of the heat slug pattern 470 subsequently formed.

In example embodiments, as shown in FIG. 3, when the heat slug pattern 470 extends in the first direction on the lower semiconductor chip 200, the heat slug pad 444 may extend in the first direction the same as an extension direction of the heat slug pattern 470.

In some example embodiments, as shown in FIG. 4, when the heat slug pattern 470 has an L-shape on the lower semiconductor chip 200 and extends the first direction and a second direction perpendicular to the first direction, the heat slug pad 444 may also extend in the first and second directions to have an L-shape like the heat slug pattern 470.

In example embodiments, the heat slug pad 444 under the heat slug pattern 470 may have a connected shape without cutting portions. For example, the heat slug pad 444 may have a single plate shape. In some example embodiments, the heat slug pad 444 under the heat slug pattern 470 may have a partially cut shape. In this case, a plurality of heat slug pads 444 may be disposed under the heat slug pattern 470.

Thereafter, a fifth upper insulation layer 440 may be formed between the first bonding pad 442 and the heat slug pad 444 on the upper redistribution layer structure 400.

The upper redistribution layer structure 400 and the first bonding pad 442 may be a rear redistribution layer (BRDL) of a fan-out package. Upper surfaces of the first bonding pad 442 and the heat slug pad 444 may be exposed to the outside.

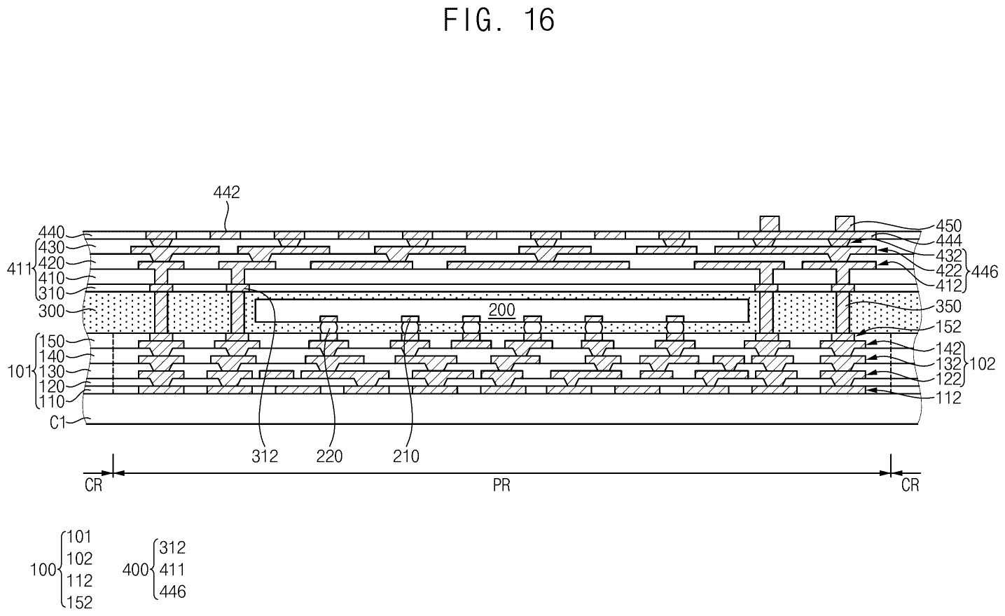

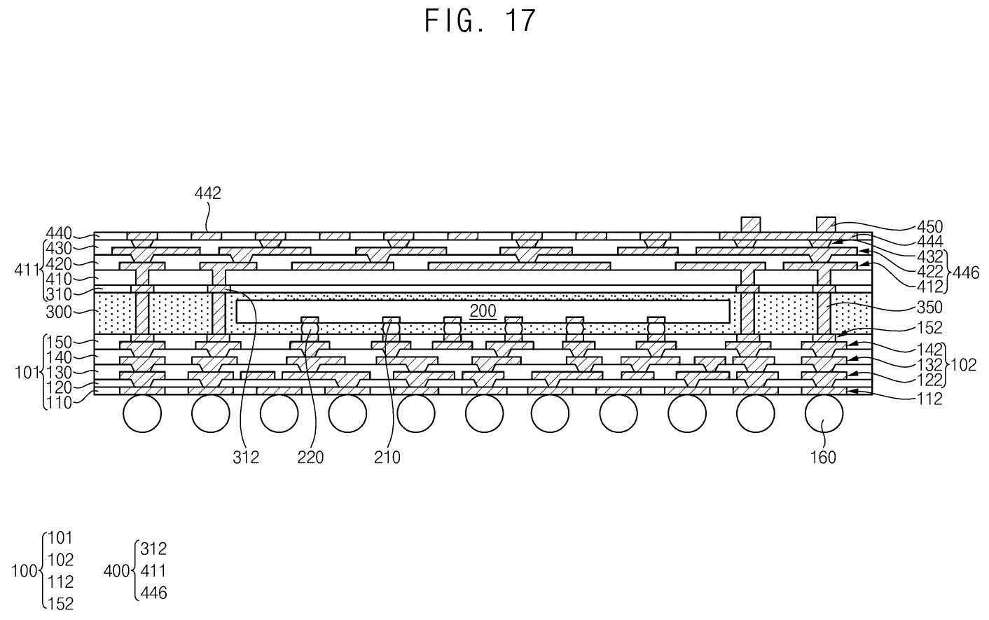

Referring to FIG. 16, heat slug posts 450 may be formed on the heat slug pad 444. The heat slug post 450 may be formed of a metal having a thermal conductivity higher than a thermal conductivity of a thermal interface material layer 460 subsequently formed. The heat slug posts 450 may be spaced apart from each other.

In example embodiments, the heat slug posts 450 may be arranged regularly and repeatedly on the heat slug pad 444. In some example embodiments, the heat slug posts 450 may be disposed on hot spots where heat dissipation is required.

In example embodiments, a photoresist layer may be formed on the heat slug pad 444, and an exposure process may be performed on the photoresist layer to form a photoresist pattern. The photoresist pattern may include tenth openings exposing the upper surface of the heat slug pad 444.

Next, a metal may at least partially fill the tenth openings of the photoresist pattern to form the heat slug posts 450 in the tenth openings. In example embodiments, the heat slug posts 450 may be formed through an electro-plating process. The heat slug post 450 may include the metal, e.g., copper. After performing the electro-plating process, a metal surface treatment process may be further performed. For example, the heat slug post 450 may include copper, and the upper surface of the copper may be covered with gold, silver, or nickel.

The heat slug post 450 may have a thermal conductivity higher than the thermal conductivity of the thermal interface material layer subsequently formed. For example, the heat slug post 450 may have the thermal conductivity of 350 W/m.k to 420 W/m.k. When the heat slug post 450 includes copper, the heat slug post 450 may have the thermal conductivity of about 400 W/m.k.

Referring to FIG. 17, the first carrier substrate C1 may be removed so that the lower surface of the lower redistribution layer structure 100 may be exposed to outside.

External connection members 160 electrically connected to the lower redistribution layers 102 may be formed on the first connection pads 112 of the lower redistribution layer structure 100.

Thereafter, a sawing process may be performed to form individual lower redistribution layer structures 100. Accordingly, a lower package including the first sealing member 300, the lower redistribution layer structure 100 formed on the lower surface of the first sealing member 300, the lower semiconductor chip 200 formed in the first sealing member 300, the upper redistribution layer structure 400, the heat slug pad 444, and the heat slug posts 450 formed on the upper surface of the first sealing member 300 may be formed.

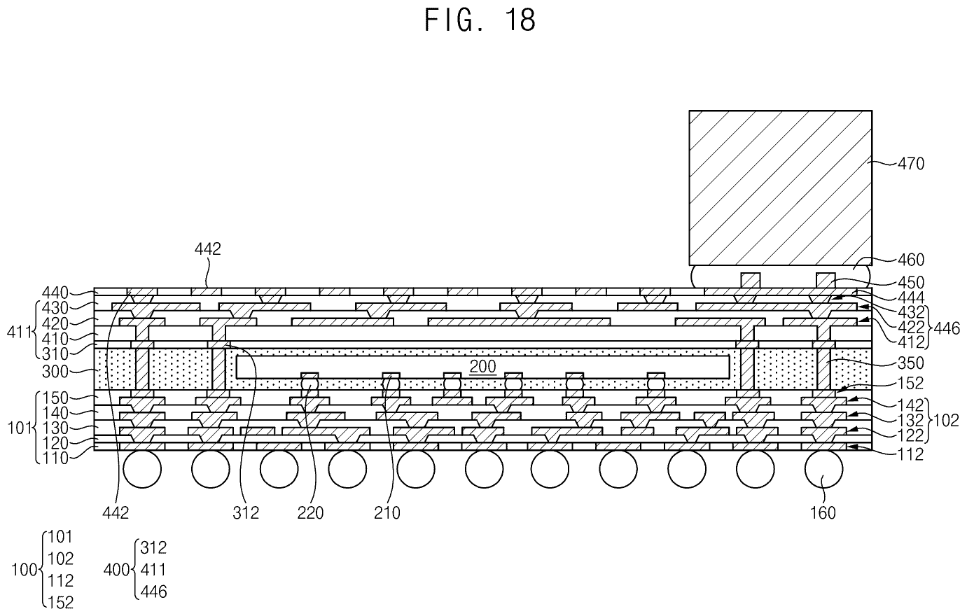

Referring to FIG. 18, a thermal interface material layer 460 may be formed on the heat slug pad 444 and the heat slug post 450 of the lower package. Additionally, a heat slug pattern 470 may be attached on the thermal interface material layer 460.

The thermal interface material layer 460 may contact an entire upper surface of the heat slug pad 444 and at least a portion of the heat slug post 450. The thermal interface material layer 460 may contact a sidewall of the heat slug post 450.

In example embodiments, the thermal interface material layer 460 may contact the upper surface of the heat slug post 450. The thermal interface material layer 460 may be disposed between the upper surface of the heat slug post 450 and the heat slug pattern 470. Accordingly, the heat slug post 450 may be spaced apart from the heat slug pattern 470.

In some example embodiments, the thermal interface material layer 460 may not be disposed between the upper surface of the heat slug post 450 and the heat slug pattern 470. Accordingly, the heat slug post 450 may contact the heat slug pattern 470.

The thermal interface material layer 460 may include grease or a thermosetting resin layer. The thermal interface material layer 460 may further include filler particles dispersed in the thermosetting resin layer. The filler particles may include metal powder or graphene powder with high thermal conductivity. Alternatively, the filler particles may include at least one of silica, alumina, zinc oxide, and nitrogen boride.

For example, the thermal interface material layer 460 may have a thermal conductivity of 2 W/m.k to 6 W/m.k.

The heat slug pattern 470 may include metal. For example, the heat slug pattern 470 may include copper, and the upper surface of the copper may be covered with gold, silver, or nickel.

In example embodiments, a portion of the heat slug pattern 470 may be arranged to overlap the lower semiconductor chip 200 included in the lower package in the vertical direction. In some example embodiments, as shown in FIG. 8, according to sizes and arrangements of the lower semiconductor chip 200 and the upper semiconductor chip 610, the heat slug pattern 470 may not be overlapped with the lower semiconductor chip 200 in the vertical direction.

The heat slug pattern 470 may be provided to dissipate heat to the outside when the lower semiconductor chip 200 included in the lower package is driven. A heat slug pad 444 and a heat slug post 450 including a metal with high thermal conductivity (e.g., copper) may be disposed to face the heat slug pattern 470. As the heat slug pad 444 and the heat slug posts 450 are included, the heat generated when the lower semiconductor chip 200 included in the lower package is driven may be easily guided to the heat slug pattern 470. Therefore, the heat may be emitted to outside through the heat slug pattern 470. Accordingly, deterioration of the semiconductor chips due to the heat generated from the semiconductor chips may be decreased.

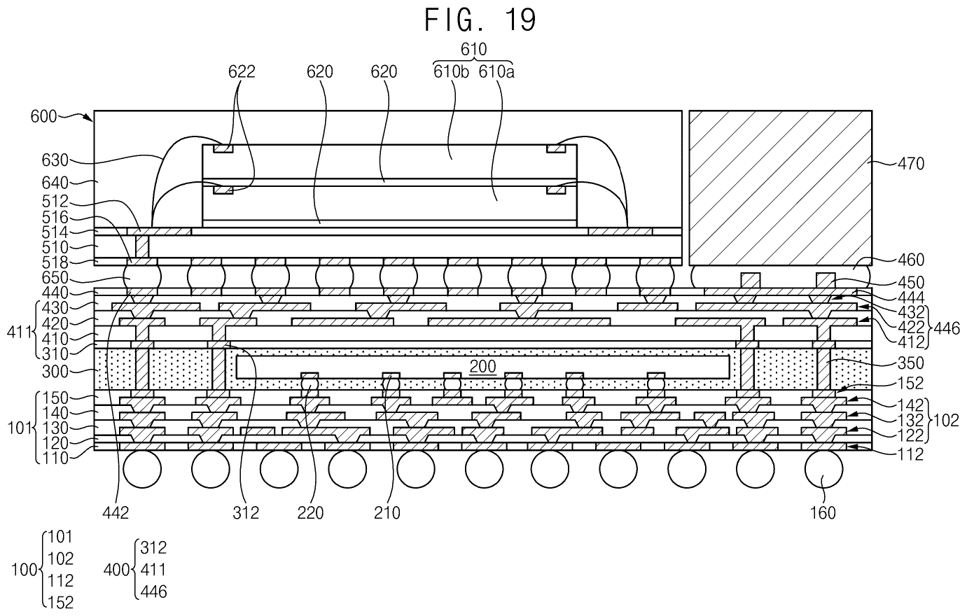

Referring to FIG. 19, the upper package 600 may be bonded on the lower package.

In example embodiments, the upper package 600 may include a package substrate 510, a plurality of upper semiconductor chips 610 mounted on the package substrate 510, a second sealing member 640 covering or overlapping the upper semiconductor chips 610 on the upper semiconductor chips 610 and a package substrate 510. The upper package 600 may further include bonding wires 630 for connecting the upper semiconductor chips 610 to each other.

In the upper package 600, the plurality of upper semiconductor chips 610 may be sequentially stacked on a package substrate 510 using adhesive members 620. The bonding wires 630 may connect the upper chip pads 622 of the upper semiconductor chips 610 to the third connection pads 512 of the package substrate 510. Insulation layers 514 may be disposed on both sides of the third connection pads 512.

In the FIG. 19, the upper package 600 may include a bonding wire 630 and two stacked semiconductor chips 610a and 610b, but the number and mounting method of the semiconductor chips in the upper package 600 may not limited be thereto.

Conductive connection members 650 may be formed on the first bonding pads 442 of the lower package, respectively, and the upper package 600 may be bonded on the conductive connection members 650.

Each of the conductive connection members 650 may include solder balls, conductive bumps, etc. Each of the conductive connection members 650 may be interposed between the first bonding pad 442 on the upper redistribution layer structure 400 and the second bonding pad 516 of the package substrate 510. Accordingly, the lower package and the upper package 600 may be electrically connected to each other by the first bonding pads 442 and the conductive connection members 650.

A semiconductor package may be manufactured by the above processes.

According to the above processes, the heat slug pad 444 including the metal with high thermal conductivity may be formed under the heat slug pattern 470, and the heat slug pad 444 may face the heat slug pattern 470. Additionally, the plurality of heat slug posts 450 may be formed on the heat slug pad 444. Therefore, the heat generated from semiconductor chips included in the semiconductor package may be quickly transferred to the heat slug pattern 470 through the heat slug pad 444 and the heat slug post 450, and the heat may be effectively dissipated to the outside through the heat slug pattern 470.

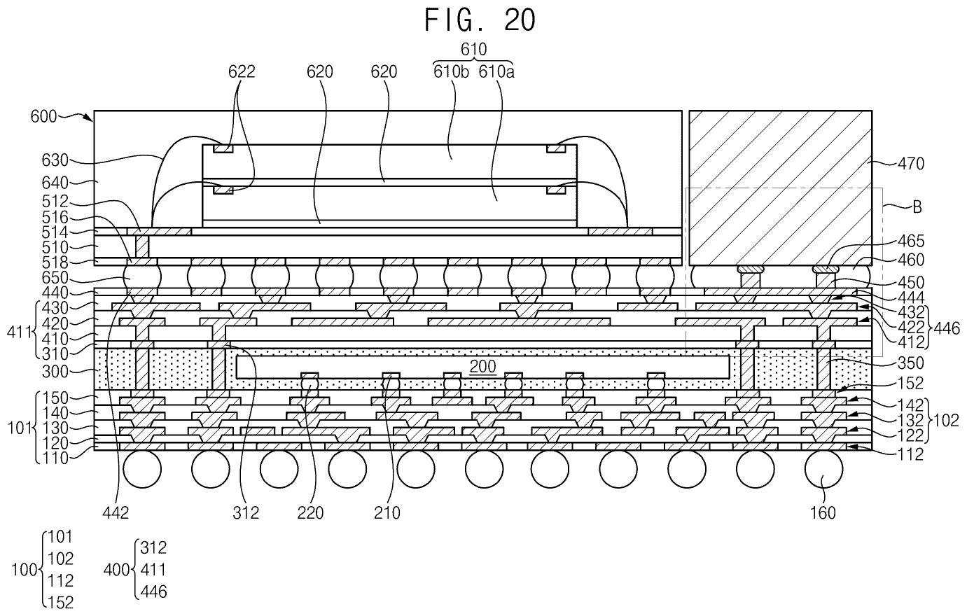

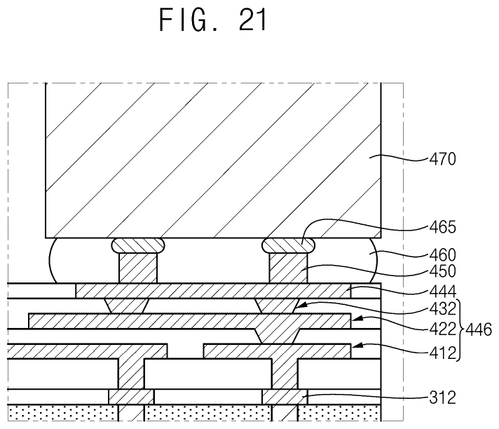

FIG. 20 is a cross-sectional view illustrating a semiconductor package according to example embodiments. FIG. 21 is an enlarged cross-sectional view illustrating an example of portion B of FIG. 20.

The semiconductor package may be substantially the same as the semiconductor package described with reference to FIG. 1, except for the heat slug structure. Accordingly, the same elements are indicated by the same reference numerals, and repeated descriptions of the same components are omitted.

Referring to FIGS. 20 and 21, the semiconductor package 11 may include the lower package, the upper package 600 and the heat slug structure disposed on the lower package.

The first bonding pad 442 and the heat slug pad 444 may be disposed on the upper redistribution layer structure 400 included in the lower package.

At least a portion of the bottom of the heat slug pad 444 may contact the upper surface of the third upper redistribution layer 432. In this case, the heat slug pad 444 may be electrically connected to a ground line (or, ground level) through the upper redistribution layer structure 400, the through via 350, the lower redistribution layers 102, and the first and second connection pads 112 and 152.

Heat slug posts 450 may be disposed on the heat slug pad 444. The heat slug posts 450 may protrude or extend from the upper surface of the heat slug pad 444.

The heat slug post 450 may be formed of a metal having a thermal conductivity higher than a thermal conductivity of the thermal interface material layer 460 subsequently formed. The heat slug post 450 may include copper. For example, the heat slug post 450 may include copper, and the upper surface of the copper may be covered with gold, silver, or nickel.

The heat slug posts 450 may be spaced apart from each other. In example embodiments, the heat slug posts 450 may be arranged regularly and repeatedly. In some example embodiments, the heat slug posts 450 may be disposed on hot spots where heat dissipation is desired.

For example, the heat slug post 450 may have the thermal conductivity of 350 W/m.k to 420 W/m.k. When the heat slug post 450 includes copper, the heat slug post 450 may have the thermal conductivity of about 400 W/m.k.

A solder bump 465 may be on an upper surface of the heat slug post 450. The solder bump 465 may include, e.g., copper (Cu), aluminum (Al), tin (Sn), nickel (Ni), gold (Au), silver (Ag), platinum (Pt), lead (Pb), or an alloy thereof.

A thermal interface material layer 460 may be disposed on the heat slug pad 444. A heat slug pattern 470 may be disposed on the thermal interface material layer 460 and the solder bump 465.

The thermal interface material layer 460 may contact an entire upper surface of the heat slug pad 444, a sidewall of the heat slug post 450, and a sidewall of the solder bump 465. The thermal interface material layer 460 may contact at least the sidewall of the heat slug post 450.

The heat slug pattern 470 may be disposed on the thermal interface material layer 460 and the solder bump 465. The heat slug pad 444, heat slug posts 450, solder bumps 465, thermal interface material layer 460, and heat slug pattern 470 may serve as a heat slug structure.

The heat slug pattern 470 may directly contact an upper surface of the solder bump 465. The solder bump 465 may be disposed between the heat slug pattern 470 and the heat slug post 450. Therefore, the heat slug pattern 470 may be electrically connected to the heat slug post 450 through the solder bump 465.

The heat slug pattern 470 may be electrically connected to a ground line through the solder bump 465, the heat slug post 450, the heat slug pad 444, the upper redistribution layer structure 400, the through via 350, the lower redistribution layers 102, and first and second connection pads 112 and 152. Even if the heat slug pattern 470 is electrically connected to the ground line, operating characteristics of the semiconductor package 11 may not change. In addition, the solder bump 465, the heat slug post 450, the heat slug pad 444, the upper redistribution layer structure 400, the through via 350, the lower redistribution layers 102 and the first and second connection pads 112 and 152 including the metal having high thermal conductivity may be connected to each other, and may be disposed under the heat slug pattern 470. Therefore, the heat generated from the semiconductor chips included in the semiconductor package 11 may be effectively transferred to the heat slug pattern 470 and dissipated to the outside through the heat slug pattern 470. Accordingly, a heat dissipation characteristic of the semiconductor package may be improved.

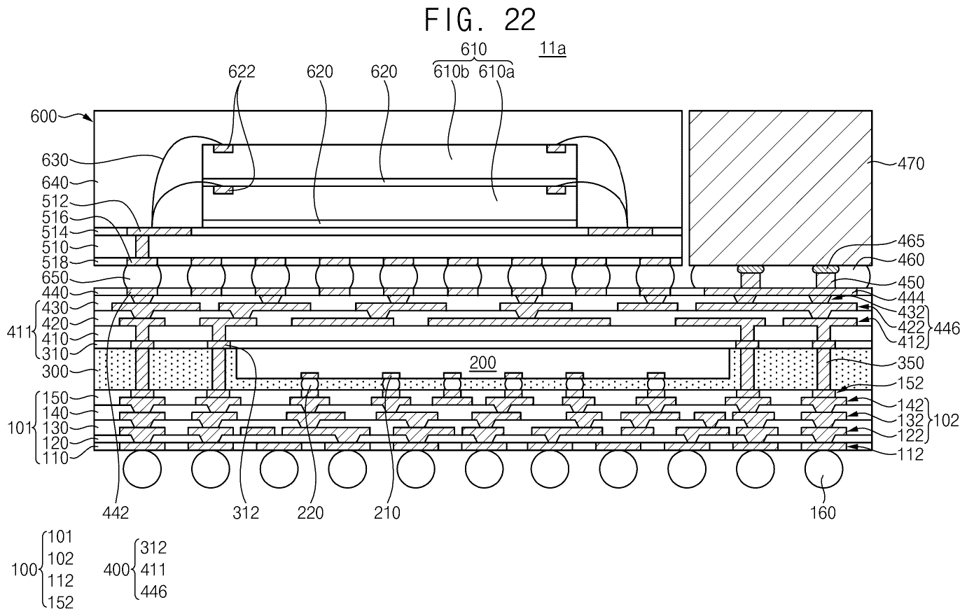

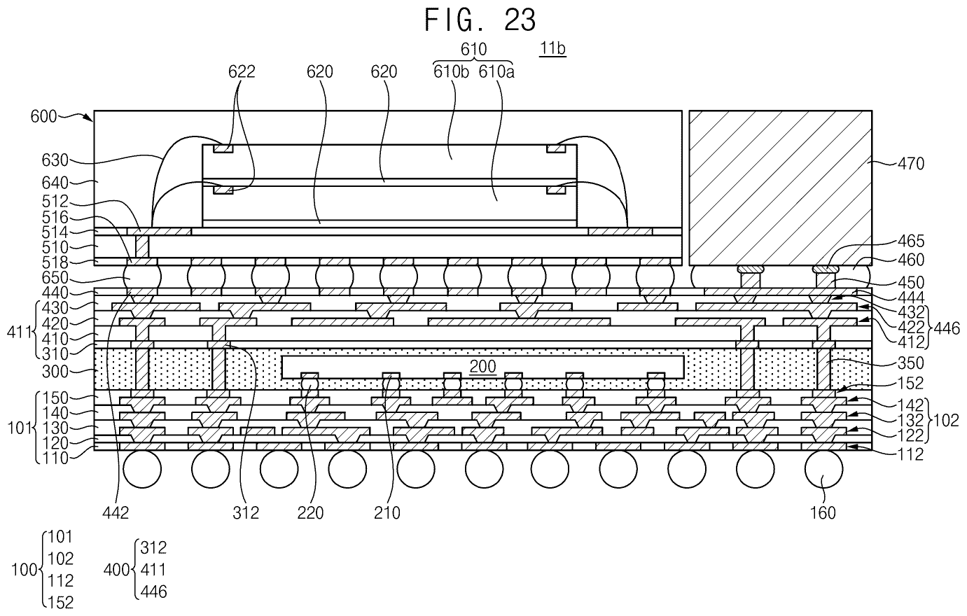

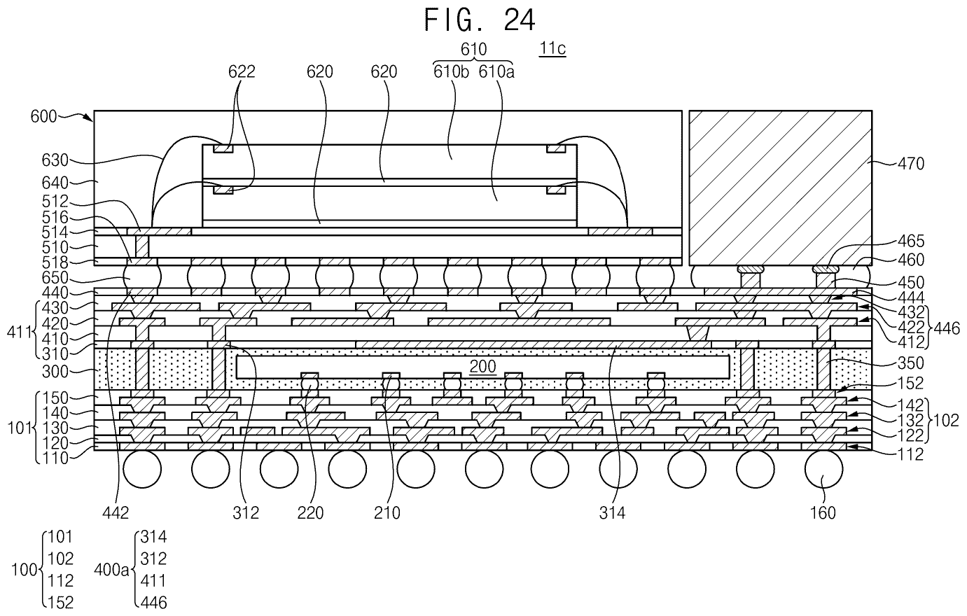

FIG. 22 is a cross-sectional view illustrating a semiconductor package according to some example embodiments. FIG. 23 is a cross-sectional view illustrating a semiconductor package according to some example embodiments. FIG. 24 is a cross-sectional view illustrating a semiconductor package according to some example embodiments.

Referring to FIG. 22, a semiconductor package 11a may have a structure in which solder bumps 465 are added to the semiconductor package shown in FIG. 7. Each of the solder bumps 465 may be disposed between the heat slug pattern 470 and the heat slug post 450. The solder bump 465 may directly contact the heat slug pattern 470 and the heat slug post 450. Therefore, the heat slug pattern 470 may be electrically connected to the heat slug post 450 through the solder bump 465.

Referring to FIG. 23, a semiconductor package 11b may have a structure in which solder bumps 465 are added to the semiconductor package shown in FIG. 8. Each of the solder bumps 465 may be disposed between the heat slug pattern 470 and the heat slug post 450.

Referring to FIG. 24, a semiconductor package 11c may have a structure in which solder bumps 465 are added to the semiconductor package shown in FIG. 9. Each of the solder bumps 465 may be disposed between the heat slug pattern 470 and the heat slug post 450.

Hereinafter, a method of manufacturing the semiconductor package shown in FIG. 20 may be described.

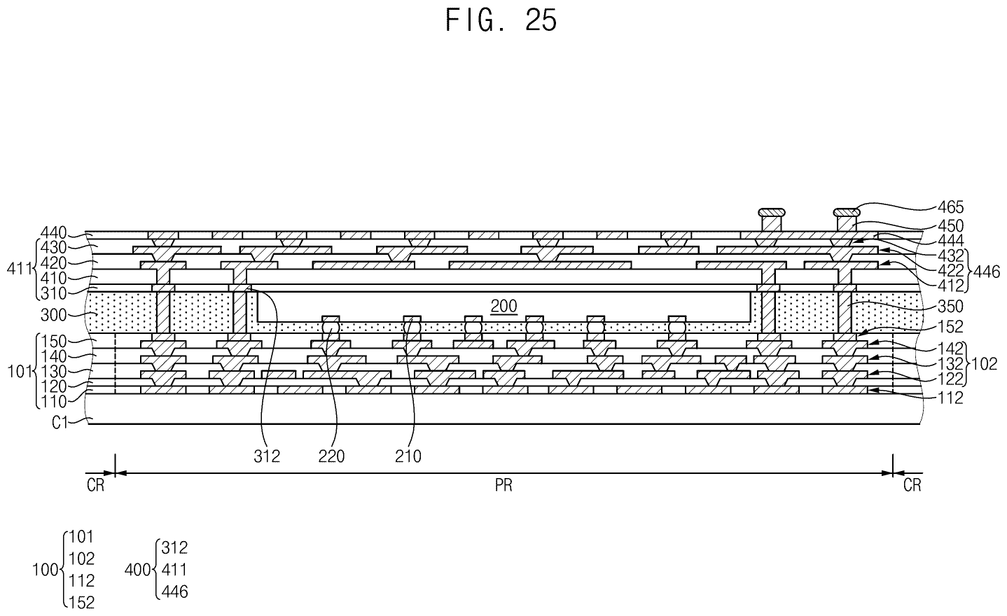

FIGS. 25 to 27 are cross-sectional views illustrating a method of manufacturing a semiconductor package according to example embodiments.

Referring to FIG. 25, first, the processes described with reference to FIGS. 10 to 16 may be performed in the same manner. In the process for forming the heat slug pad with reference to FIG. 15, at least a portion of a bottom of the heat slug pad 444 may contact an upper surface of the third upper redistribution 432. In addition, the heat slug pad 444 may be electrically connected to a ground line through the upper redistribution layer structure 400, the through via 350, the lower redistribution layer 102, and the first and second connection pads 112 and 152.

Thereafter, solder bumps 465 may be formed on the heat slug posts 450, respectively. Each of the solder bumps 465 may include copper (Cu), aluminum (Al), tin (Sn), nickel (Ni), gold (Au), silver (Ag), platinum (Pt), lead (Pb), or an alloy thereof.

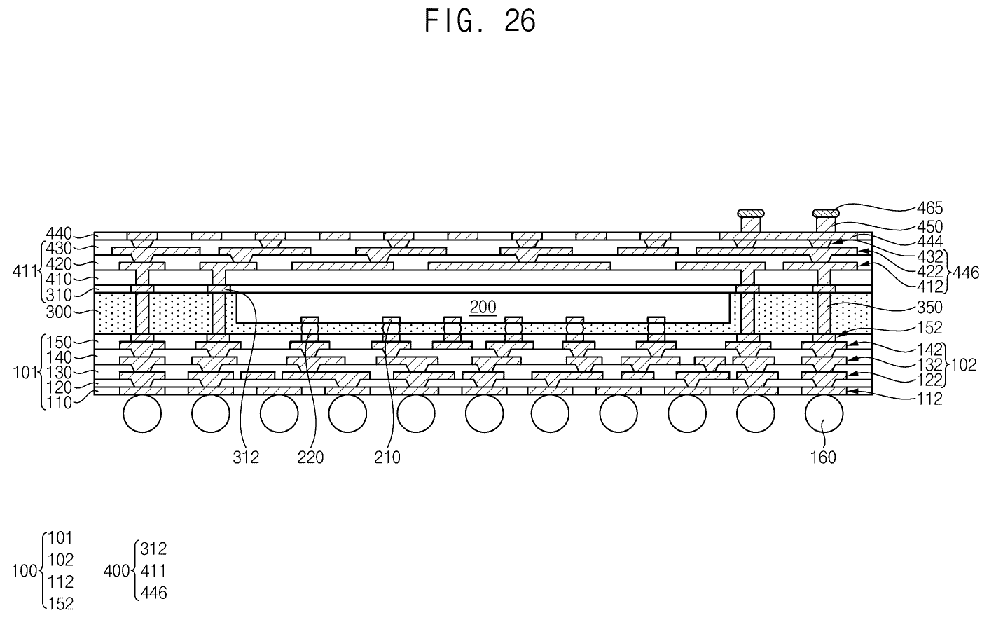

Referring to FIG. 26, the same process described with reference to FIG. 17 may be performed on the structure. Accordingly, a lower package including the first sealing member 300, the lower redistribution layer structure 100 formed on a lower surface of the first sealing member 300, the lower semiconductor chip 200 formed in the first sealing member 300, the upper redistribution layer structure 400, the heat slug pad 444, the heat slug posts 450 and the solder bumps 465 formed on the upper surface of the first sealing member 300 may be formed.

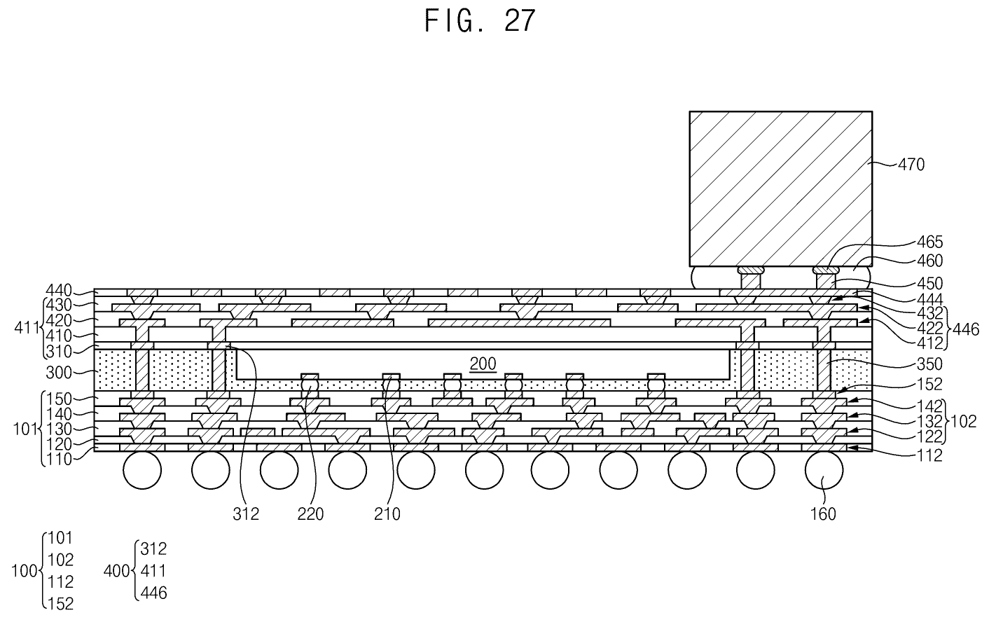

Referring to FIG. 27, a thermal interface material layer 460 may be formed on the heat slug pad 444 of the lower package. Additionally, a heat slug pattern 470 may be attached on the thermal interface material layer 460.

In the process, the heat slug pattern 470 and the solder bump 465 may directly contact to each other by a soldering process of the solder bump 465. Therefore, the heat slug pattern 470 may be electrically connected to the heat slug post 450 through the solder bump 465.

In example embodiments, the soldering process may be performed by a mass flow bonding process or a thermo-compression bonding process.

Sequentially, the process described with reference to FIG. 19 may be performed in the same manner to manufacture the semiconductor package 11 shown in FIG. 20.

According to the above process, the heat slug pad 444 including the metal with high thermal conductivity may be formed under the heat slug pattern 470, and the heat slug pad 444 may face the heat slug pattern 470 in the vertical direction. Additionally, the plurality of heat slug posts 450 and solder bumps including the metal with high thermal conductivity are formed on the heat slug pad 444, and the solder bumps 465 may directly contact the heat slug pattern 470. Accordingly, heat generated from semiconductor chips included in the semiconductor package may be quickly transferred to the heat slug pattern 470, and the heat may be effectively dissipated to the outside through the heat slug pattern 470.

The semiconductor package may include semiconductor devices such as logic devices or memory devices. The semiconductor package may include, e.g., logic devices such as a central processing unit (CPU, MPU), an application processor (AP), volatile memory devices such as an SRAM device, and a DRAM device, and non-volatile memory devices such as flash memory devices, PRAM devices, MRAM devices, and RRAM devices, etc.

While the present disclosure has been shown and described with reference to example embodiments thereof, it will be understood by those of ordinary skill in the art that various changes in form and details may be made thereto without departing from the scope of the present disclosure as set forth by the following claims.

What is claimed is:

1. A semiconductor package, comprising:
a lower redistribution layer structure comprising lower redistribution layers;
a lower semiconductor chip on the lower redistribution layer structure, the lower semiconductor chip electrically connected to the lower redistribution layers;
a sealing member on the lower semiconductor chip;
through vias extending into the sealing member, each of the through vias electrically connected to the lower redistribution layer structure;
an upper redistribution layer structure on the sealing member, the upper redistribution layer structure comprising upper redistribution layers electrically connected to the through vias;
a bonding pad and a heat slug pad on the upper redistribution layer structure;
an upper package on the bonding pad, the upper package comprising at least one upper semiconductor chip;
a plurality of heat slug posts on the heat slug pad;
a thermal interface material layer on the heat slug pad and the plurality of heat slug posts; and
a heat slug pattern on the thermal interface material layer,
wherein the bonding pad is electrically connected to the upper redistribution layers, and
wherein a thermal conductivity of the heat slug pad and a thermal conductivity of the plurality of heat slug posts is greater than a thermal conductivity of the thermal interface material layer.

2. The semiconductor package of claim 1, wherein the bonding pad and the heat slug pad comprise a same metal.

3. The semiconductor package of claim 2, wherein the bonding pad and the heat slug pad comprise copper (Cu), aluminum (Al), tin (Sn), nickel (Ni), gold (Au), platinum (Pt), or an alloy thereof.

4. The semiconductor package of claim 1, wherein the plurality of heat slug posts comprise copper (Cu), aluminum (Al), tin (Sn), nickel (Ni), gold (Au), platinum (Pt), or an alloy thereof.

5. The semiconductor package of claim 1, wherein the heat slug pad is spaced apart from the upper redistribution layers in a direction that is perpendicular to a lower surface of the lower redistribution layer structure, and wherein the heat slug pad does not contact the upper redistribution layers.

6. The semiconductor package of claim 1, wherein the plurality of heat slug posts and the heat slug pattern are spaced apart from each other in a direction that is perpendicular to a lower surface of the lower redistribution layer structure, and wherein the thermal interface material layer is between the plurality of heat slug posts and the heat slug pattern.

7. The semiconductor package of claim 1, wherein at least a portion of the heat slug pad contacts the upper redistribution layers.

8. The semiconductor package of claim 7, further comprising solder bumps that respectively directly contact the plurality of heat slug posts and directly contact the heat slug pattern.

9. The semiconductor package of claim 8, wherein the heat slug pattern is electrically connected to a ground level through the solder bumps, the plurality of heat slug posts, the heat slug pad, and the upper redistribution layers.

10. The semiconductor package of claim 1, wherein a portion of the heat slug pattern overlaps the lower semiconductor chip in a direction that is perpendicular to a lower surface of the lower redistribution layer structure.

11. The semiconductor package of claim 1, wherein the heat slug pad is disposed to face the heat slug pattern in a direction that is perpendicular to a lower surface of the lower redistribution layer structure.

12. The semiconductor package of claim 1, wherein the upper redistribution layer structure further comprises a lower heat slug pattern electrically connected to the heat slug pad, and wherein at least a portion of the lower heat slug pattern faces the lower semiconductor chip.

13. A semiconductor package, comprising:
a lower package comprising a lower redistribution layer structure, a lower semiconductor chip, and an upper redistribution layer structure;
a bonding pad and a heat slug pad on the lower package, the bonding pad and the heat slug pad comprising a same metal;
an upper package on the bonding pad, the upper package electrically connected to the bonding pad and comprising at least one upper semiconductor chip;
a plurality of heat slug posts on the heat slug pad;
a thermal interface material layer on the heat slug pad and the plurality of heat slug posts; and
a heat slug pattern on the thermal interface material layer,
wherein the heat slug pad faces the heat slug pattern in a first direction that is perpendicular to a lower surface of the lower package.

14. The semiconductor package of claim 13, wherein a thermal conductivity of the heat slug pad and a thermal conductivity of the plurality of heat slug posts are greater than a thermal conductivity of the thermal interface material layer.

15. The semiconductor package of claim 13, wherein the heat slug pad is spaced apart from upper redistribution layers of the upper redistribution layer structure in the first direction, and the heat slug pad does not contact the upper redistribution layers.

16. The semiconductor package of claim 13, wherein at least a portion of the heat slug pad contacts upper redistribution layers of the upper redistribution layer structure.

17. The semiconductor package of claim 16, further comprising solder bumps that respectively directly contact the plurality of heat slug posts and the heat slug pattern.

18. The semiconductor package of claim 17, wherein the heat slug pattern is electrically connected to a ground level through the solder bumps, the plurality of heat slug posts, the heat slug pad, and the upper redistribution layer structure.

19. A semiconductor package, comprising:
a lower redistribution layer structure comprising lower redistribution layers;
a lower semiconductor chip on the lower redistribution layer structure, the lower semiconductor chip electrically connected to the lower redistribution layers;
a sealing member on the lower semiconductor chip;
through vias extending into the sealing member and electrically connected to the lower redistribution layers, the through vias at least partially surrounding the lower semiconductor chip;
an upper redistribution layer structure on the sealing member, the upper redistribution layer structure comprising upper redistribution layers electrically connected to the through vias;
a bonding pad and a heat slug pad on the upper redistribution layer structure;
an upper package on the bonding pad and electrically connected to upper redistribution layers through the bonding pad, the upper package comprising at least one upper semiconductor chip;
a plurality of heat slug posts on the heat slug pad;
a thermal interface material layer on the heat slug pad and the heat slug posts; and
a heat slug pattern on the thermal interface material layer,
wherein the heat slug pattern is spaced apart from at least one sidewall of the upper package in a direction that is parallel to a lower surface of the lower redistribution layer structure.

20. The semiconductor package of claim 19, further comprising solder bumps that respectively directly contact the plurality of heat slug posts and directly contact the heat slug pattern.
